(19) United States
(12) Patent Application Publication
(10) Pub. No.: US 2025/0006695 A1
(43) Pub. Date: Jan. 2, 2025

(54) PACKAGING ARCHITECTURE INCLUDING COMPENSATION LAYERS FOR WAFER-SCALE KNOWN-GOOD-DIE TO KNOWN-GOOD-DIE HYBRID BONDING

(71) Applicant: Intel Corporation, Santa Clara, CA (US)

(72) Inventors: Bhaskar Jyoti Krishnatreya, Hillsboro, OR (US); Adel A. Elsherbini, Chandler, AZ (US); Brandon M. Rawlings, Chandler, AZ (US); Kimin Jun, Portland, OR (US); Omkar G. Karhade, Chandler, AZ (US); Mohit Bhatia, Chandler, AZ (US); Nitin A. Deshpande, Chandler, AZ (US); Prashant Majhi, San Jose, CA (US); Johanna M. Swan, Scottsdale, AZ (US)

(73) Assignee: Intel Corporation, Santa Clara, CA (US)

(21) Appl. No.: 18/344,260

(22) Filed: Jun. 29, 2023

(51) Int. Cl. H01L 25/065; H01L 23/00; H01L 23/31; H01L 23/48

(52) U.S. Cl. CPC H01L 25/0652; H01L 23/3157; H01L 23/481; H01L 24/08; H01L 2224/08145

(57) ABSTRACT

Microelectronic assemblies, related devices and methods, are disclosed herein. In some embodiments, a microelectronic assembly may include a first layer with a first die having a first contact; a second die having a second contact; and a pad layer, on the first and second dies, including a first pad and a second pad, where the first pad is coupled to and offset from the first contact in a first direction, and the second pad is coupled to and is offset from the second contact in a second direction different than the first direction; and a second layer including a third die having third and fourth contacts, where the first layer is coupled to the second layer by metal-to-metal bonds and fusion bonds, the first contact is coupled to the third contact by the first pad, and the second contact is coupled to the fourth contact by the second pad.

### TECHNICAL FIELD

The present disclosure relates to techniques, methods, and apparatus directed to packaging architecture for wafer-scale known-good-die (KGD) to KGD hybrid bonding.

### BACKGROUND

Electronic circuits when commonly fabricated on a wafer of semiconductor material, such as silicon, are called integrated circuits (ICs). The wafer with such ICs is typically cut into numerous individual dies. The dies may be packaged into an IC package containing one or more dies along with other electronic components such as resistors, capacitors, and inductors. The IC package may be integrated onto an electronic system, such as a consumer electronic system, or servers, such as mainframes.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 is a schematic of plan views of two layers of dies for bonding together and a stacked view according to some embodiments of the present disclosure.

FIG. 2 is a schematic of plan views of two layers of dies and a compensation layer for bonding together and a stacked view according to some embodiments of the present disclosure.

FIG. 3 is a schematic cross-sectional view of another example microelectronic assembly according to some embodiments of the present disclosure.

FIG. 4A is a schematic of stacked views of two dies and two compensation layers for bonding together according to some embodiments of the present disclosure.

FIG. 4B is a schematic of other stacked views of two dies and two compensation layers for bonding together according to some embodiments of the present disclosure.

FIG. 5 is a schematic cross-sectional view of another example microelectronic assembly according to some embodiments of the present disclosure.

FIGS. 6A and 6B are schematic cross-sectional views of other example microelectronic assemblies according to some embodiments of the present disclosure.

FIGS. 7A and 7B are schematic cross-sectional views of other example microelectronic assemblies according to some embodiments of the present disclosure.

FIGS. 8A-8E are schematic cross-sectional views of various stages of manufacture of an example microelectronic assembly according to some embodiments of the present disclosure.

FIG. 9 is a schematic flow diagram listing example operations that may be associated with fabricating a microelectronic assembly according to some embodiments of the present disclosure.

FIG. 10 is a top view of a wafer and dies that may be included in a microelectronic assembly, in accordance with any of the embodiments disclosed herein.

FIG. 11 is a cross-sectional side view of an IC device that may be included in a microelectronic assembly, in accordance with any of the embodiments disclosed herein.

FIG. 12 is a cross-sectional view of an IC device package that may include one or more microelectronic assemblies in accordance with any of the embodiments disclosed herein.

FIG. 13 is a cross-sectional side view of an IC device assembly that may include a microelectronic assembly, in accordance with any of the embodiments disclosed herein.

FIG. 14 is a block diagram of an example electrical device that may include a microelectronic assembly, in accordance with any of the embodiments disclosed herein.

### DETAILED DESCRIPTION

### Overview

For purposes of illustrating IC packages described herein, it is important to understand phenomena that may come into play during assembly and packaging of ICs. The following foundational information may be viewed as a basis from which the present disclosure may be properly explained. Such information is offered for purposes of explanation only and, accordingly, should not be construed in any way to limit the broad scope of the present disclosure and its potential applications.

Advances in semiconductor processing and logic design have permitted an increase in the amount of logic circuits that may be included in processors and other IC devices. As a result, many processors now have multiple cores that are monolithically integrated on a single die. Generally, these types of monolithic ICs are also described as planar since they take the form of a flat surface and are typically built on a single silicon wafer made from a monocrystalline silicon boule. The typical manufacturing process for such monolithic ICs is called a planar process, allowing photolithography, etching, heat diffusion, oxidation, and other such processes to occur on the surface of the wafer, such that active circuit elements (e.g., transistors and diodes) are formed on the planar surface of the silicon wafer.

Current technologies permit hundreds and thousands of such active circuit elements to be formed on a single die so that numerous logic circuits may be enabled thereon. In such monolithic dies, the manufacturing process must be optimized for all the circuits equally, resulting in trade-offs between different circuits. In addition, because of the limitation of having to place circuits on a planar surface, some circuits are farther apart from some others, resulting in decreased performance such as longer delays. The manufacturing yield may also be severely impacted because the entire die may have to be discarded if even one circuit is malfunctional.

One solution to overcome such negative impacts of monolithic dies is to disaggregate the circuits into smaller dies (e.g., chiplets. tiles) electrically coupled by interconnect bridges. The smaller dies are part of an assembly of interconnected dies that together form a complete IC in terms of application and/or functionality, such as a memory chip, microprocessor, microcontroller, commodity IC (e.g., chip used for repetitive processing routines, simple tasks, application specific IC, etc.), and system-on-chip (SOC). In other words, the individual dies are connected together to create the functionalities of a monolithic IC. By using separate dies, each individual die can be designed and manufactured optimally for a particular functionality. For example, a processor core that contains logic circuits might aim for performance, and thus might require a very speed-optimized layout. This has different manufacturing requirements compared to a USB controller, which is built to meet certain USB standards, rather than for processing speed. Thus, by having different parts of the overall design separated into different dies, each one optimized in terms of design and manufacturing, the overall yield and cost of the combined die solution may be improved.

The connectivity between these dies is achievable by many different ways. For example, in 2.5D packaging solutions, a silicon interposer and through-silicon vias (TSVs) connect dies at silicon interconnect speed in a minimal footprint. In another example, a silicon bridge embedded under the edges of two interconnecting dies facilitates electrical coupling between them. In a three-dimensional (3D) architecture, the dies are stacked one above the other, creating a smaller footprint overall. Typically, the electrical connectivity and mechanical coupling in such 3D architecture is achieved using TSVs and high pitch solder-based bumps (e.g., C2 interconnections). The silicon bridge and the 3D stacked architecture may also be combined, which allows for top-packaged chips to communicate with other chips horizontally using the silicon bridge and vertically, using Through-Mold Vias (TMVs) which are typically larger than TSVs. Yet another packaging architecture uses hybrid bonding processes to form high-density interconnects between stacks of dies in a true 3D configuration. Hybrid bonding technology allows for much smaller interconnect pitches of less than 100 nanometers, which allows for interconnect densities of greater than 10M IOs/millimeters².

Wafer-level processing cannot be performed because a single wafer may have more than one die that is non-functional; attaching such non-functional dies to a good die wastes resources and decreases overall manufacturing yield. Wafer-to-wafer hybrid bonding process can provide good bonding yields but generally do not enable multiple KGD on top of a base die or singulated die testing. Die-to-wafer hybrid bonding process is prone to defects due to foreign materials being introduced on bonding surface during dicing, chemical mechanical polishing, grinding, thinning, etc. Collective bonding of singulated dies on wafer can enable fast hybrid bonding but it is sensitive to defects from die singulation, thinning as well as die thickness variations. Cleaning of dies after singulation can mitigate some of the defects of die to wafer bonding, but while it is suitable in theory, in practice, it is difficult to achieve complete cleaning without damaging the bonding surfaces.

One solution for wafer-to-wafer hybrid bonding is to reconstitute KGDs on a carrier, using die bonders, to form a known-good-wafer (KGW) and, subsequently, bond one KGW to another KGW. However, die bonders have limited die placement capabilities, which typically results in misalignment errors and bonding defects between KGDs of the KGWs. Further, wafer-to-wafer hybrid bonding requires the two bonding surfaces to have interconnect contacts that are mirror images (e.g., have conductive bonds on each surface that match up to form an interconnect, where the two bonding surfaces do not have to be uniform, but should be mapped such that the conductive bonds on each surface align with each other for bonding). Any alteration in the bonding pad alignment may result in poor contact or no contact of interconnects, which may cause an IC package or an electronic assembly to fail. Bonding pad alignment is a significant challenge as it impacts the ability to bond KGDs to KGDs during package assembly. Incomplete interconnects produce yield losses during assembly, which increases costs especially in heterogenous packages because multiple dies are discarded even if only a single die fails. As such, bonding pad alignment is therefore a major problem for package designs, especially for wafer-on-wafer processes using reconstituted KGDs. Various ones of the embodiments disclosed herein may help achieve improved bonding pad alignment with smaller interconnect pitches relative to conventional approaches. Disclosed herein are apparatuses and method where, after the KGWs are created, compensation layers are added to a top surface of the KGWs, for example, using adaptive patterning techniques, which measures and calculates individual KGD placement errors to pattern the compensation layers, and subsequently forming hybrid bond layers on a top surface of the compensation layers. A compensation layer may correct for the individual KGD placement errors such that after the hybrid bond layers are created, the hybrid bonding layers for both KGWs may be symmetric for optimal bond overlay and may further provide a continuous electrical pathway through the compensation layers.

Accordingly, microelectronic assemblies, related devices and methods, are disclosed herein. In some embodiments, a microelectronic assembly may include a first layer with a first die having a first conductive contact; a second die having a second conductive contact; and a pad layer on the first die and the second die, the pad layer including a first pad and a second pad, where the first pad is coupled to the first conductive contact and is offset from the first conductive contact in a first direction, and the second pad is coupled to the second conductive contact and is offset from the second conductive contact in a second direction different than the first direction; and a second layer including a third die having a third conductive contact and a fourth conductive contact, where the first layer is coupled to the second layer by an interconnect layer having metal-to-metal bonds and fusion bonds, the first conductive contact is coupled to the third conductive contact by the first pad and one or more of the metal-to-metal bonds, and the second conductive contact is coupled to the fourth conductive contact by the second pad and one or more of the metal-to-metal bonds.

Each of the structures, assemblies, packages, methods, devices, and systems of the present disclosure may have several innovative aspects, no single one of which is solely responsible for all the desirable attributes disclosed herein. Details of one or more implementations of the subject matter described in this specification are set forth in the description below and the accompanying drawings.

In the following detailed description, various aspects of the illustrative implementations may be described using terms commonly employed by those skilled in the art to convey the substance of their work to others skilled in the art.

The terms “circuit” and “circuitry” mean one or more passive and/or active electrical and/or electronic components that are arranged to cooperate with one another to provide a desired function. The terms also refer to analog circuitry, digital circuitry, hard wired circuitry, programmable circuitry, microcontroller circuitry and/or any other type of physical hardware electrical and/or electronic component.

The term “integrated circuit” means a circuit that is integrated into a monolithic semiconductor or analogous material.

In some embodiments, the IC dies disclosed herein may comprise substantially monocrystalline semiconductors, such as silicon or germanium, as a base material (e.g., substrate, body) on which integrated circuits are fabricated with traditional semiconductor processing methods. The semiconductor base material may include, for example, N-type pr P-type materials. Dies may include, for example, a crystalline base material formed using a bulk silicon (or other bulk semiconductor material) or a silicon-on-insulator (SOI) structure. In some other embodiments, the base material of one or more of the IC dies may comprise alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-N, group III-V, group II-VI, or group IV materials. In yet other embodiments, the base material may comprise compound semiconductors, for example, with a first sub-lattice of at least one element from group III of the periodic table (e.g., Al, Ga, In), and a second sub-lattice of at least one element of group V of the periodic table (e.g., P, As, Sb). In yet other embodiments, the base material may comprise an intrinsic IV or III-V semiconductor material or alloy, not intentionally doped with any electrically active impurity; in alternate embodiments, nominal impurity dopant levels may be present. In still other embodiments, dies may comprise a non-crystalline material, such as polymers; for example, the base material may comprise silica-filled epoxy. In other embodiments, the base material may comprise high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, the base material may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphide, and black phosphorus, each of which may possibly be doped with one or more of gallium, indium, aluminum, fluorine, boron, phosphorus, arsenic, nitrogen, tantalum, tungsten, and magnesium, etc. Although a few examples of the material for dies are described here, any material or structure that may serve as a foundation (e.g., base material) upon which IC circuits and structures as described herein may be built falls within the spirit and scope of the present disclosure.

Unless described otherwise, IC dies described herein include one or more IC structures (or, simply, “ICs”) implementing (i.e., configured to perform) certain functionality. In one such example, the term “memory die” may be used to describe a die that includes one or more ICs implementing memory circuitry (e.g., ICs implementing one or more of memory devices, memory arrays, control logic configured to control the memory devices and arrays, etc.). In another such example, the term “compute die” may be used to describe a die that includes one or more ICs implementing logic/compute circuitry (e.g., ICs implementing one or more of I/O functions, arithmetic operations, pipelining of data, etc.).

In another example, the terms “package” and “IC package” are synonymous, as are the terms “die” and “IC die.” Note that the terms “chip,” “die,” and “IC die” are used interchangeably herein.

The term “insulating” means “electrically insulating,” the term “conducting” means “electrically conducting,” unless otherwise specified. With reference to optical signals and/or devices, components and elements that operate on or using optical signals, the term “conducting” can also mean “optically conducting.”

The terms “oxide,” “carbide,” “nitride,” etc. refer to compounds containing, respectively, oxygen, carbon, nitrogen, etc.

The term “high-k dielectric” refers to a material having a higher dielectric constant than silicon oxide, while the term “low-k dielectric” refers to a material having a lower dielectric constant than silicon oxide.

The term “insulating material” or “insulator” (also called herein as “dielectric material” or “dielectric”) refers to solid materials (and/or liquid materials that solidify after processing as described herein) that are substantially electrically nonconducting. They may include, as examples and not as limitations, organic polymers and plastics, epoxy mold compound (EMC), and inorganic materials such as ionic crystals, porcelain, glass, silicon, silicon oxide, silicon carbide, silicon oxycarbide, silicon carbon nitride, silicon nitride, and alumina or a combination thereof. They may include dielectric materials, high polarizability materials, and/or piezoelectric materials. They may be transparent or opaque without departing from the scope of the present disclosure. Further examples of insulating materials are underfills and molds or mold-like materials used in packaging applications, including for example, materials used in organic interposers, package supports and other such components.

In various embodiments, elements associated with an IC may include, for example, transistors, diodes, power sources, resistors, capacitors, inductors, sensors, transceivers, receivers, antennas, etc. In various embodiments, elements associated with an IC may include those that are monolithically integrated within an IC, mounted on an IC, or those connected to an IC. The ICs described herein may be either analog or digital and may be used in a number of applications, such as microprocessors, optoelectronics, logic blocks, audio amplifiers, etc., depending on the components associated with the IC. The ICs described herein may be employed in a single IC die or as part of a chipset for executing one or more related functions in a computer.

In various embodiments of the present disclosure, transistors described herein may be field-effect transistors (FETs), e.g., MOSFETs. In general, a FET is a three-terminal device that includes source, drain, and gate terminals and uses electric field to control current flowing through the device. A FET typically includes a channel material, a source region and a drain regions provided in and/or over the channel material, and a gate stack that includes a gate electrode material, alternatively referred to as a “work function” material, provided over a portion of the channel material (the “channel portion”) between the source and the drain regions, and optionally, also includes a gate dielectric material between the gate electrode material and the channel material.

In a general sense, an “interconnect” refers to any element that provides a physical connection between two other elements. For example, an electrical interconnect provides electrical connectivity between two electrical components, facilitating communication of electrical signals between them; an optical interconnect provides optical connectivity between two optical components, facilitating communication of optical signals between them. As used herein, both electrical interconnects and optical interconnects are comprised in the term “interconnect.” The nature of the interconnect being described is to be understood herein with reference to the signal medium associated therewith. Thus, when used with reference to an electronic device, such as an IC that operates using electrical signals, the term “interconnect” describes any element formed of an electrically conductive material for providing electrical connectivity to one or more elements associated with the IC or/and between various such elements. In such cases, the term “interconnect” may refer to both conductive traces (also sometimes referred to as “lines,” “wires,” “metal lines” or “trenches”) and conductive vias (also sometimes referred to as “vias” or “metal vias”). Sometimes, electrically conductive traces and vias may be referred to as “conductive traces” and “conductive vias”, respectively, to highlight the fact that these elements include electrically conductive materials such as metals. Likewise, when used with reference to a device that operates on optical signals as well, such as a photonic IC (PIC), “interconnect” may also describe any element formed of a material that is optically conductive for providing optical connectivity to one or more elements associated with the PCI. In such cases, the term “interconnect” may refer to optical waveguides, including optical fiber, optical splitters, optical combiners, optical couplers, and optical vias.

The term “waveguide” refers to any structure that acts to guide the propagation of light from one location to another location typically through a substrate material such as silicon or glass. In various examples, waveguides can be formed from silicon, doped silicon, silicon nitride, glasses such as silica (e.g., silicon dioxide or SiO₂), borosilicate (e.g., 70-80 wt % SiO₂, 7-13 wt % of B203, 4-8 wt % Na₂O or K₂O, and 2-8 wt % of Al₂O₃) and so forth. Waveguides may be formed using various techniques including but not limited to forming waveguides in situ. For example, in some embodiments, waveguides may be formed in situ in glass using low temperature glass-to-glass bonding or by laser direct writing. Waveguides formed in situ may have lower loss characteristics.

The term “conductive trace” may be used to describe an electrically conductive element isolated by an insulating material. Within IC dies, such insulating material comprises interlayer low-k dielectric that is provided within the IC die. Within package substrates, and printed circuit boards (PCBs) such insulating material comprises organic materials such as Ajinomoto Buildup Film (ABF), polyimides, or epoxy resin. Such conductive lines are typically arranged in several levels, or several layers, of metallization stacks.

The term “conductive via” may be used to describe an electrically conductive element that interconnects two or more conductive lines of different levels of a metallization stack. To that end, a via may be provided substantially perpendicularly to the plane of an IC die/chip or a support structure over which an IC structure is provided and may interconnect two conductive lines in adjacent levels or two conductive lines in non-adjacent levels.

The term “package substrate” may be used to describe any substrate material that facilitates the packaging together of any collection of semiconductor dies and/or other electrical components such as passive electrical components. As used herein, a package substrate may be formed of any material including, but not limited to, insulating materials such as resin impregnated glass fibers (e.g., PCB or Printed Wiring Boards (PWB)), glass, ceramic, silicon, silicon carbide, etc. In addition, as used herein, a package substrate may refer to a substrate that includes buildup layers (e.g., ABF layers).

The term “metallization stack” may be used to refer to a stack of one or more interconnects for providing connectivity to different circuit components of an IC die/chip and/or a package substrate.

As used herein, the term “pitch” of interconnects refers to a center-to-center distance between adjacent interconnects.

It will be recognized that one or more levels of underfill (e.g., organic polymer material such as benzotriazole, imidazole, polyimide, or epoxy) may be provided in an IC package described herein and may not be labeled in order to avoid cluttering the drawings. In various embodiments, the levels of underfill may comprise the same or different insulating materials. In some embodiments, the levels of underfill may comprise thermoset epoxies with silicon oxide particles or an EMC; in some embodiments, the levels of underfill may comprise any suitable material that can perform underfill functions such as supporting the dies and reducing thermal stress on interconnects. In some embodiments, the choice of underfill material may be based on design considerations, such as form factor, size, stress, operating conditions, etc.; in other embodiments, the choice of underfill material may be based on material properties and processing conditions, such as cure temperature, glass transition temperature, viscosity and chemical resistance, among other factors; in some embodiments, the choice of underfill material may be based on both design and processing considerations.

In some embodiments, one or more levels of solder resist (e.g., epoxy liquid, liquid photoimageable polymers, dry film photoimageable polymers, acrylics, solvents) may be provided in an IC package described herein and may not be labeled or shown to avoid cluttering the drawings. Solder resist may be a liquid or dry film material including photoimageable polymers. In some embodiments, solder resist may be non-photoimageable.

The terms “substantially,” “close,” “approximately,” “near,” and “about,” generally refer to being within +/−20% of a target value (e.g., within +/−5% or 10% of a target value) based on the context of a particular value as described herein or as known in the art.

Terms indicating orientation of various elements, e.g., “coplanar,” “perpendicular,” “orthogonal,” “parallel,” or any other angle between the elements, generally refer to being within +/−5%-20% of a target value based on the context of a particular value as described herein or as known in the art.

The term “connected” means a direct connection (which may be one or more of a mechanical, electrical, and/or thermal connection) between the things that are connected, without any intermediary devices, while the term “coupled” means either a direct connection between the things that are connected, or an indirect connection through one or more passive or active intermediary devices.

The description uses the phrases “in an embodiment” or “in embodiments,” which may each refer to one or more of the same or different embodiments.

Furthermore, the terms “comprising,” “including,” “having,” and the like, as used with respect to embodiments of the present disclosure, are synonymous.

The disclosure may use perspective-based descriptions such as “above,” “below,” “top,” “bottom,” and “side”; such descriptions are used to facilitate the discussion and are not intended to restrict the application of disclosed embodiments.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with one or both of the two layers or may have one or more intervening layers. In contrast, a first layer described to be “on” a second layer refers to a layer that is in direct contact with that second layer. Similarly, unless explicitly stated otherwise, one feature disposed between two features may be in direct contact with the adjacent features or may have one or more intervening layers.

The term “dispose” as used herein refers to position, location, placement, and/or arrangement rather than to any particular method of formation.

The term “between,” when used with reference to measurement ranges, is inclusive of the ends of the measurement ranges.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). When used herein, the notation “A/B/C” means (A), (B), and/or (C).

Although certain elements may be referred to in the singular herein, such elements may include multiple sub-elements. For example,” an electrically conductive material” may include one or more electrically conductive materials. In another example, “a dielectric material” may include one or more dielectric materials.

Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, reference is made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

The accompanying drawings are not necessarily drawn to scale.

In the drawings, same reference numerals refer to the same or analogous elements/materials shown so that, unless stated otherwise, explanations of an element/material with a given reference numeral provided in context of one of the drawings are applicable to other drawings where element/materials with the same reference numerals may be illustrated. Further, the singular and plural forms of the labels may be used with reference numerals to denote a single one and multiple ones respectively of the same or analogous type, species, or class of element.

Furthermore, in the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using, e.g., images of suitable characterization tools such as scanning electron microscopy (SEM) images, transmission electron microscope (TEM) images, or non-contact profilometer. In such images of real structures, possible processing and/or surface defects could also be visible, e.g., surface roughness, curvature or profile deviation, pit or scratches, not-perfectly straight edges of materials, tapered vias or other openings, inadvertent rounding of corners or variations in thicknesses of different material layers, occasional screw, edge, or combination dislocations within the crystalline region(s), and/or occasional dislocation defects of single atoms or clusters of atoms. There may be other defects not listed here but that are common within the field of device fabrication and/or packaging.

Note that in the figures, various components (e.g., interconnects) are shown as aligned (e.g., at respective interfaces) merely for ease of illustration; in actuality, some or all of them may be misaligned. In addition, there may be other components, such as bond pads, landing pads, metallization, etc. present in the assembly that are not shown in the figures to prevent cluttering. Further, the figures are intended to show relative arrangements of the components within their assemblies, and, in general, such assemblies may include other components that are not illustrated (e.g., various interfacial layers or various other components related to optical functionality, electrical connectivity, or thermal mitigation). For example, in some further embodiments, the assembly as shown in the figures may include more dies along with other electrical components. Additionally, although some components of the assemblies are illustrated in the figures as being planar rectangles or formed of rectangular solids, this is simply for ease of illustration, and embodiments of these assemblies may be curved, rounded, or otherwise irregularly shaped as dictated by and sometimes inevitable due to the manufacturing processes used to fabricate various components.

In the drawings, a particular number and arrangement of structures and components are presented for illustrative purposes and any desired number or arrangement of such structures and components may be present in various embodiments.

Further, unless otherwise specified, the structures shown in the figures may take any suitable form or shape according to material properties, fabrication processes, and operating conditions.

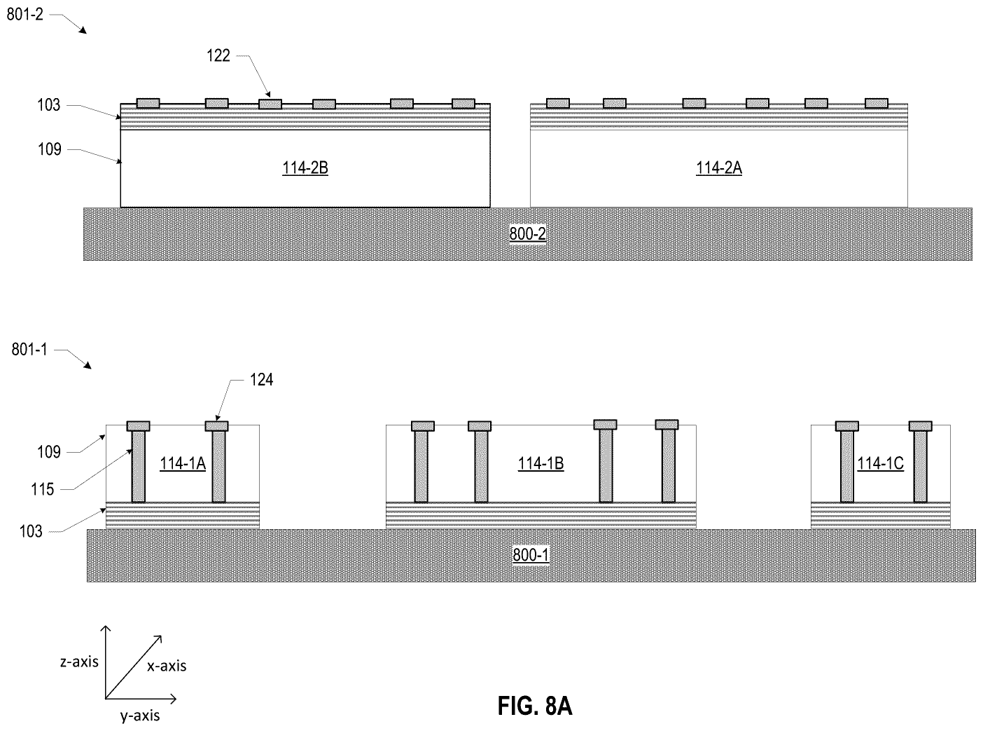

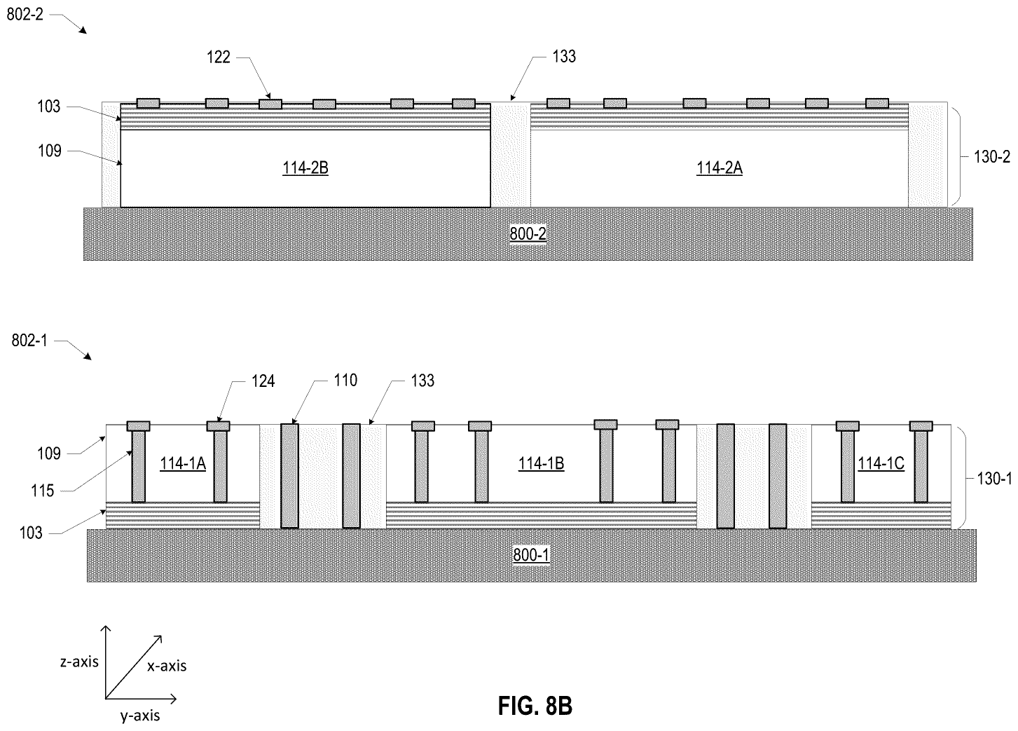

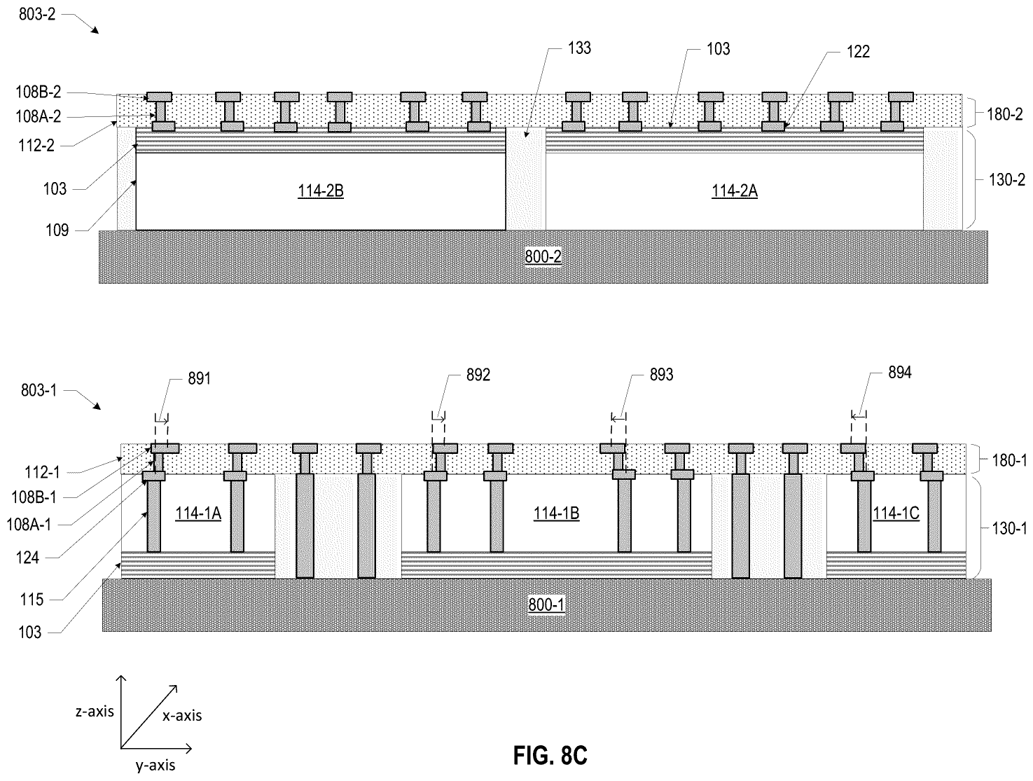

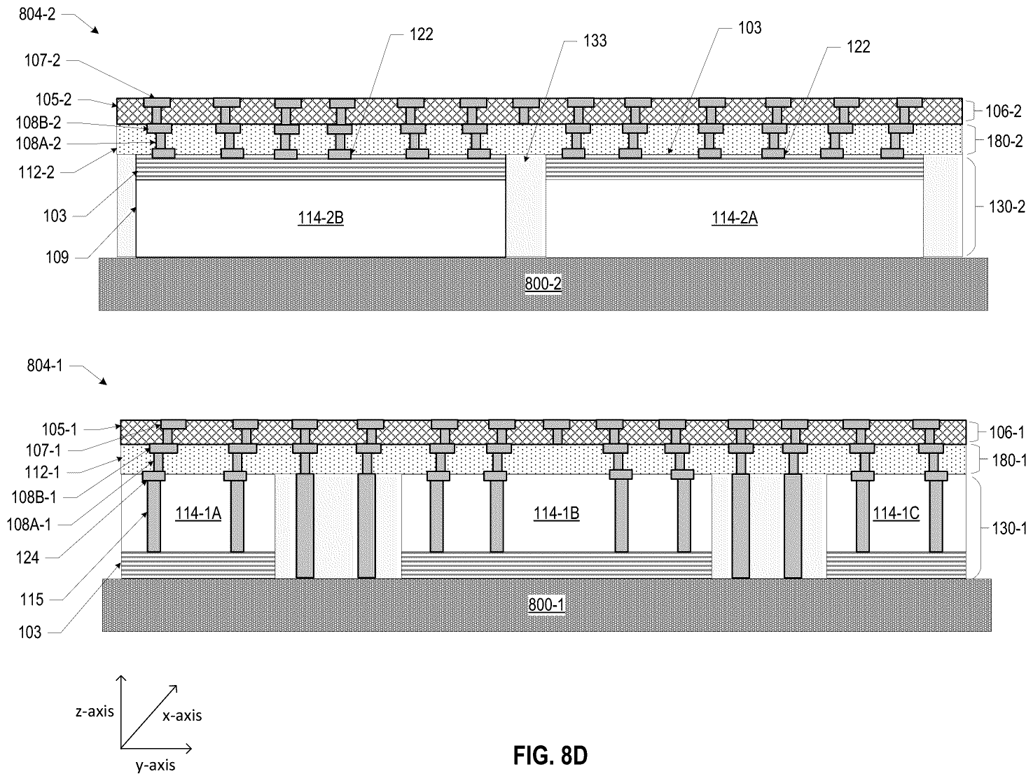

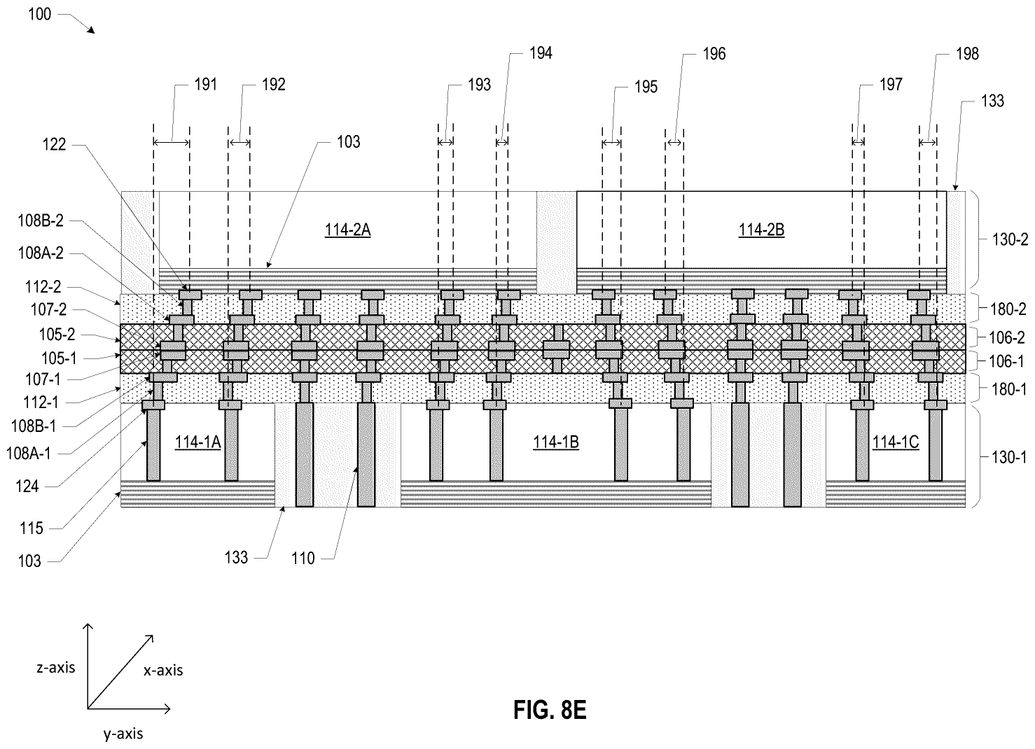

For convenience, if a collection of drawings designated with different letters are present (e.g., FIGS. 8A-8E), such a collection may be referred to herein without the letters (e.g., as “FIG. 8”). Similarly, if a collection of reference numerals designated with different numerals and/or letters are present (e.g., 114-1, 114-2, or 108A-1, 108A-2, 108B-1, 108B-2), such a collection may be referred to herein without the numerals and/or letters (e.g., as “114” or “108A” or “108”).

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

### Example Embodiments

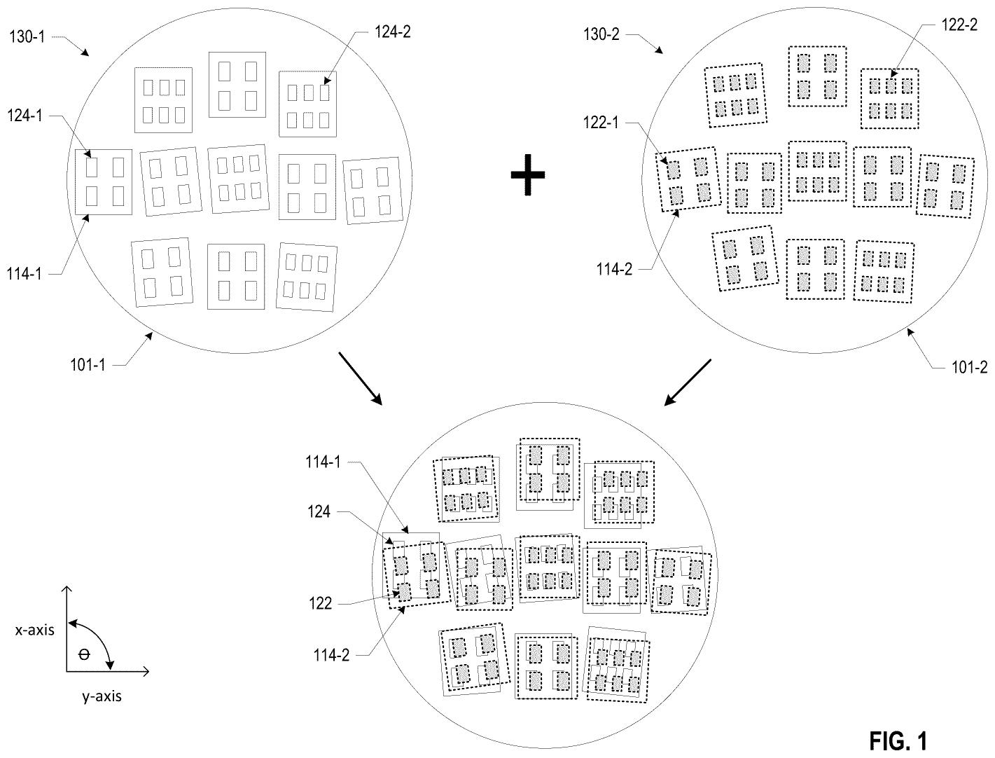

FIG. 1 is a schematic of plan views of two layers of dies for bonding together and a stacked view according to some embodiments of the present disclosure. The first layer 130-1 may be reconstituted KGDs (e.g., dies 114-1) on a carrier 101-1 (e.g., a first wafer), and the second layer 130-2 may be reconstituted KGDs (e.g., dies 114-2) on another carrier 101-2 (e.g., a second wafer). A wafer having reconstituted KGDs may be referred to herein as a KGW. The dies 114-1 may include conductive contacts 124 on a surface, and the conductive contacts 124 may include conductive contacts 124-1, 124-2 having different pitches. The dies 114-2 may include conductive contacts 122 on a surface, and the conductive contacts 122 may include conductive contacts 122-1, 122-2 having different pitches and arranged in different arrays. The reconstituted dies 114-1, 114-2 may be placed using any suitable technique, such as a die bonder. The die bonder may have limited placement accuracy for aligning the conductive contacts 124 of the dies 114-1 to the conductive contacts 122 of the dies 114-2 when the first layer 130-1 is stacked on the second layer 130-2 for bonding. The conductive contacts 122, 124 may be misaligned along a width (e.g., y-direction), a length (e.g., x-direction), and/or an angle of rotation (e.g., theta (O)). In fact, as shown in the stacked illustration (e.g., the illustration on the bottom), the conductive contacts 124 of the die 114-1 and the conductive contacts 122 of the die 114-2 may be misaligned such that an interconnect may not be formed (e.g., leading to opens or infinite resistance) or an interconnect may be formed with a neighboring contact (e.g., leading to shorts).

Accordingly, embodiments disclosed herein include architectures that enable the use of compensation layers for aligning and electrically coupling the conductive contacts 124 of the die 114-1 to the conductive contacts 122 of the die 114-2.

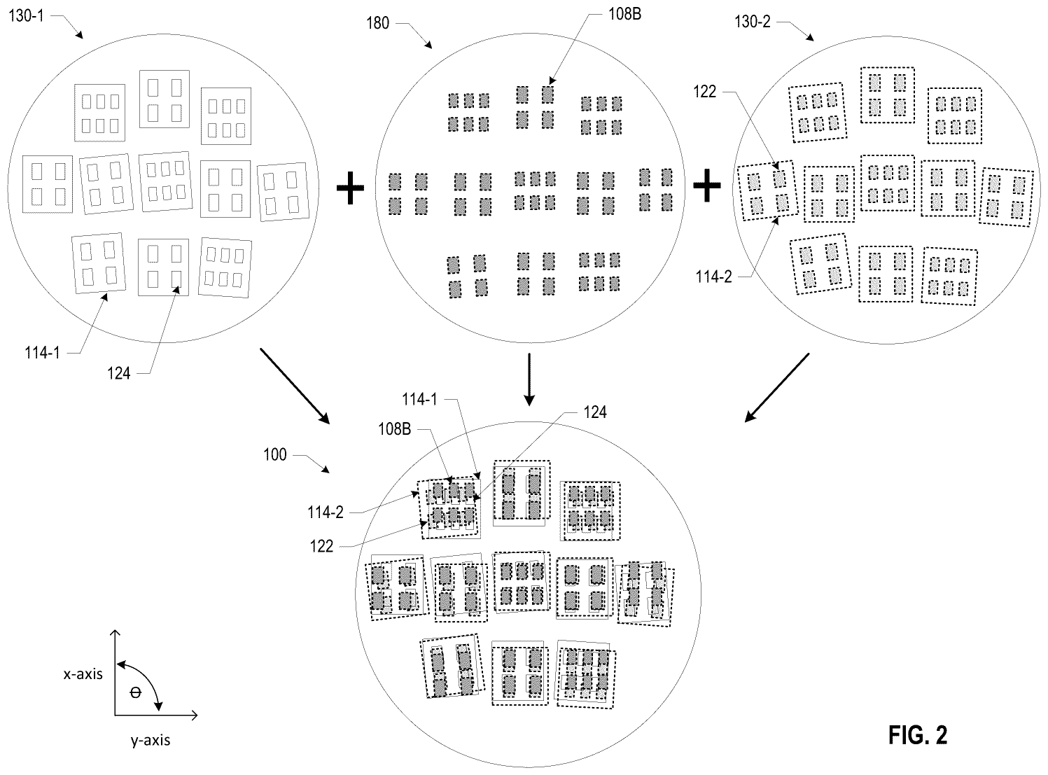

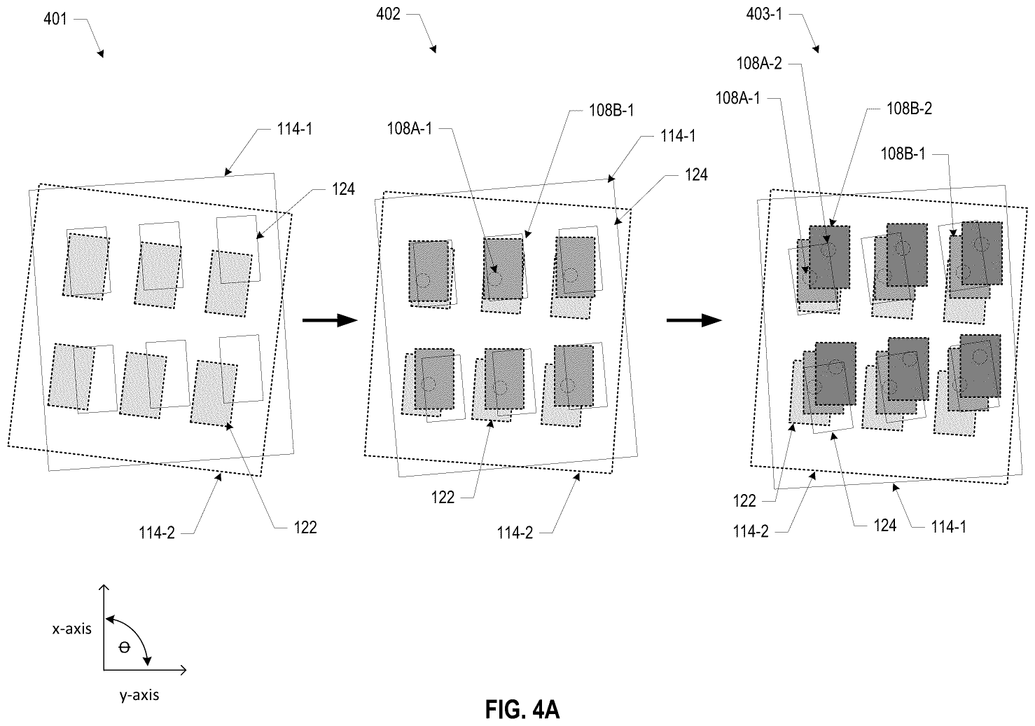

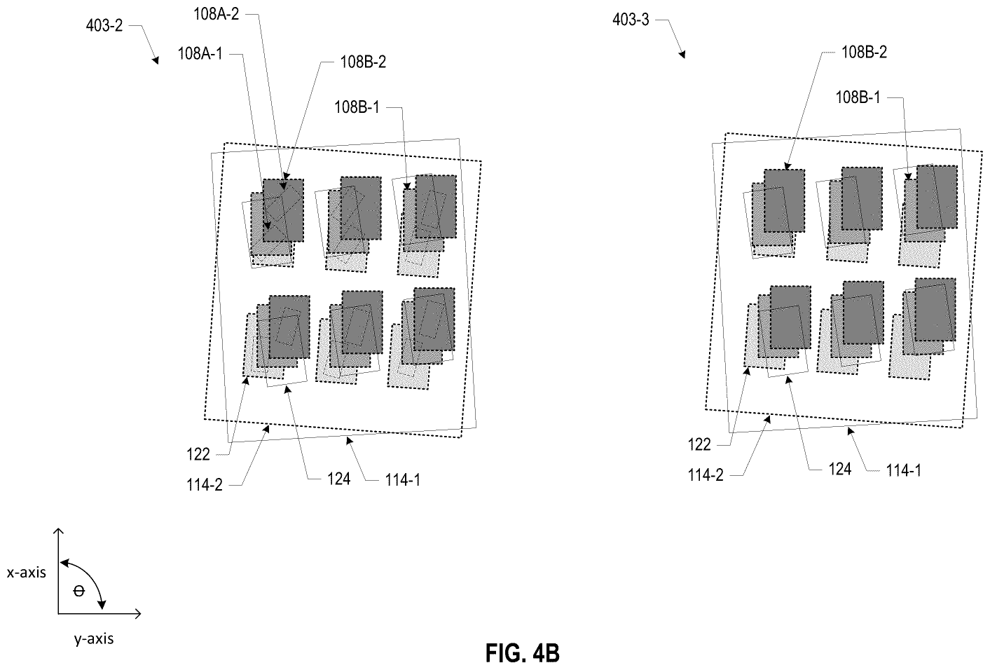

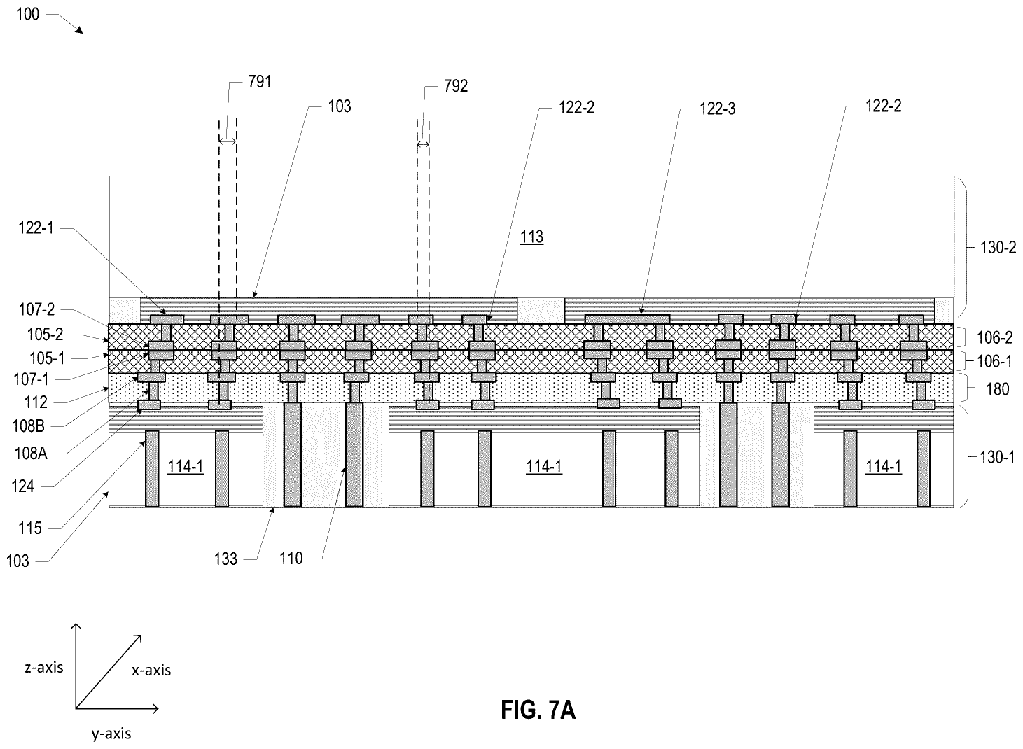

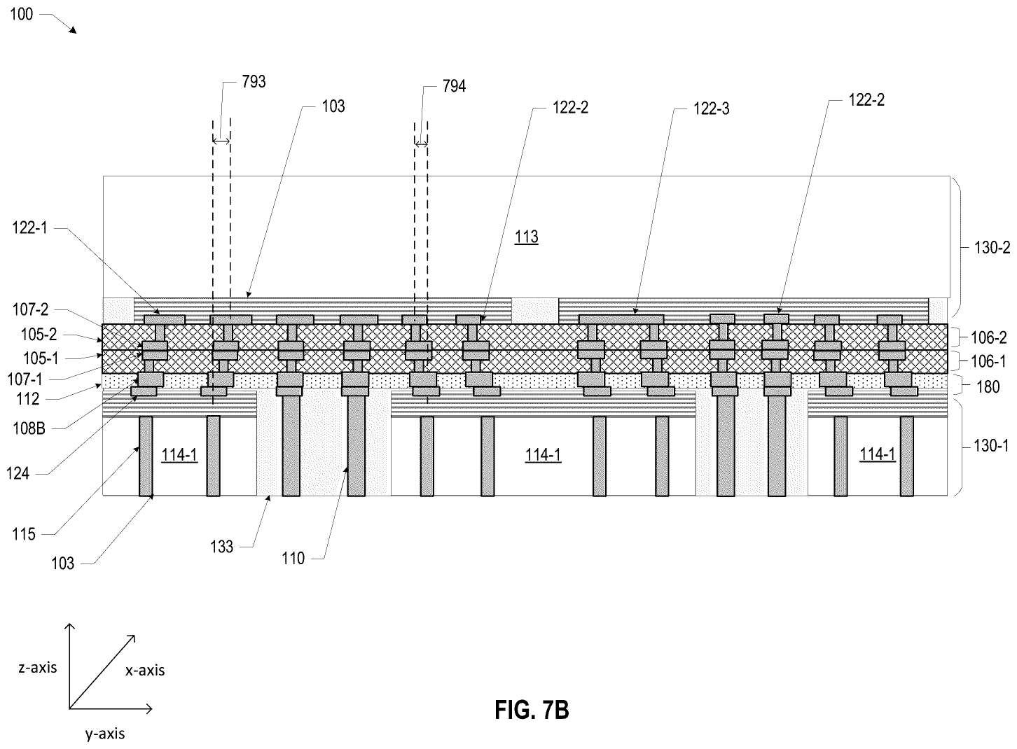

FIG. 2 is a schematic of plan views of two layers of dies and a compensation layer for bonding together and a stacked view according to some embodiments of the present disclosure. FIG. 2 shows the first layer 130-1 having reconstituted KGDs (e.g., dies 114-1) on a carrier 101-1 of FIG. 1 and the second layer 130-2 may be reconstituted KGDs (e.g., dies 114-2) on another carrier 101-2, also of FIG. 1, and further shows a compensation layer 180, also referred to herein as a “pad layer,” having conductive pads 108B. In some embodiments, the compensation layer 180 may further include conductive features 108A, such as vias (e.g., as shown in assembly 403-1 in FIG. 4A) or traces (e.g., as shown in assembly 403-2 in FIG. 4B), coupled to the conductive pads 108B for coupling the layers together. In some embodiments, the compensation layer 180 may include only conductive pads 108B coupled to conductive contacts 122, 124 (e.g., as shown in assembly 403-3 in FIG. 4B and as shown in FIG. 7B). The compensation layer 180 may be stacked between the first layer 130-1 and the second layer 130-2. The conductive pads 108B of the compensation layer 180 may reroute the interconnections such that the conductive contacts 124 of the die 114-1 may be coupled to the conductive contacts 122 of the die 114-2. In some embodiments, the first layer 130-1 or the second layer 130-2 is an unsingulated wafer.

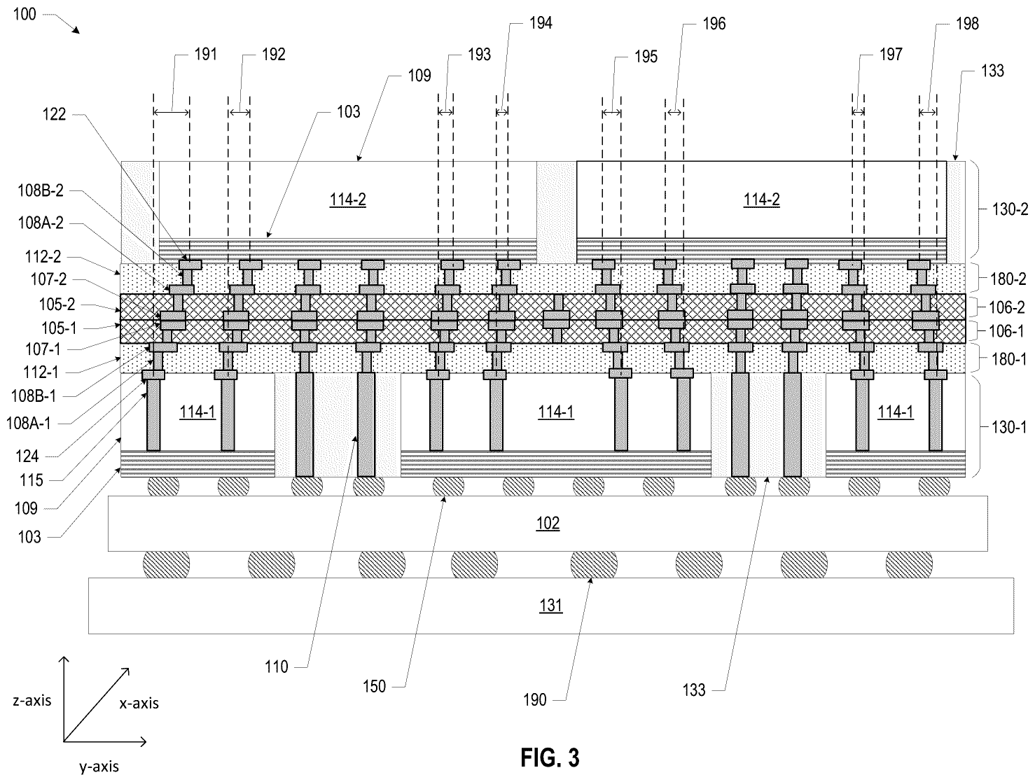

FIG. 3 is a schematic cross-sectional view of an example microelectronic assembly 100 according to some embodiments of the present disclosure. Microelectronic assembly 100, comprises, in the embodiment shown, a stack of layers 130 (e.g., 130-1, 130-2) coupled by at least a compensation layer (e.g., 180-1, 180-2) and hybrid bonding (HB) interconnects 106. Layer 130-1 may include dies 114-1 (e.g., reconstituted KGDs that have functional ICs) surrounded by an insulating material 133. In a general sense, a KGD is typically a semiconductor die with ICs that have passed various testing operations, such as wafer probe, burn-in, functional test, screening, etc., and are operating within design parameters. The KGDs are manufactured in wafer form, singulated, tested (before or after singulation), and screened before being used in microelectronic assembly 100. Dies 114-1 may include a substrate 109, a metallization stack 103 (e.g., a back-end-of-line (BEOL) stack), and through-silicon vias (TSVs) 115 coupling conductive contacts 124 to the metallization stack 103. Layer 130-1 may further include a via 110 that extends through the layer 130-1.

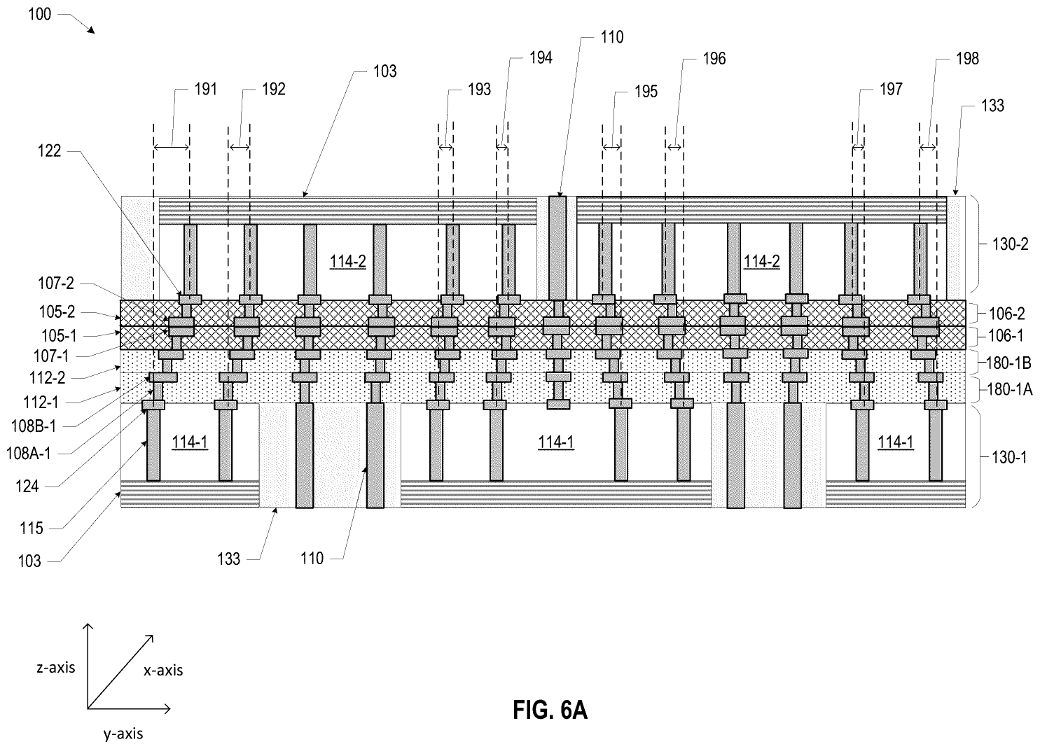

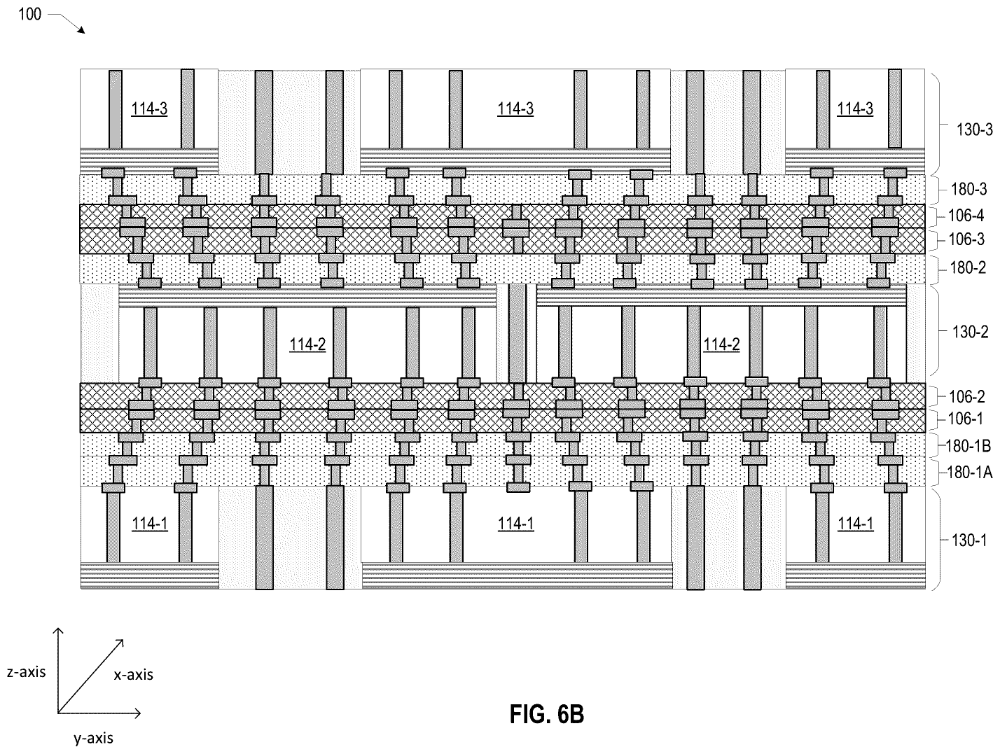

Layer 130-2 may include dies 114-2 (e.g., reconstituted KGDs that have functional ICs) surrounded by an insulating material 133. Dies 114-2 may include a substrate 109 and a metallization stack 103 coupled to conductive contacts 122. Die 114-1 may be coupled to die 114-2 in a back-to-front configuration where the front side (e.g., metallization stack 103) of die 114-2 is coupled to a back side of die 114-1. Conductive contacts 122, 124 may have multiple pitches and/or dimensions (e.g., as shown in FIG. 7). Layer 130-2 may further include a via 110 (e.g., as shown in FIG. 6) that extends through the layer 130-2. An insulating material 133 that encapsulates the die 114 (e.g., on and around die 114 in layers 130-1, 130-2) may include an inorganic material such as silicon oxide or organic material such as resin, epoxy, or a combination such as mold material (organic polymer with embedded inorganic particles e.g. silicon oxide, aluminum oxide, etc.).

The die 114 disclosed herein may include an insulating material (e.g., a dielectric material formed in multiple layers, as known in the art) and multiple conductive pathways formed through the insulating material. In some embodiments, the insulating material of a die 114 may include a dielectric material, such as silicon dioxide, silicon nitride, silicon oxynitride, silicon carbon nitride, polyimide materials, glass reinforced epoxy matrix materials, or a low-k or ultra low-k dielectric (e.g., carbon-doped dielectrics, fluorine-doped dielectrics, porous dielectrics, organic polymeric dielectrics, an EMC, photo-imageable dielectrics, and/or benzocyclobutene-based polymers). In some embodiments, the insulating material of a die 114 may include a semiconductor material, such as silicon, germanium, or a III-V material (e.g., gallium nitride), and one or more additional materials. For example, an insulating material may include silicon oxide or silicon nitride. The conductive pathways in a die 114 may include conductive traces and/or conductive vias, and may connect any of the conductive contacts in the die 114 in any suitable manner (e.g., connecting multiple conductive contacts on a same surface or on different surfaces of the die 114). The conductive pathways in the dies 114 may be bordered by liner materials, such as adhesion liners and/or barrier liners, as suitable. In some embodiments, the die 114 is a wafer. In some embodiments, the die 114 is a monolithic silicon, a fan-out or fan-in package die, or a die stack (e.g., wafer stacked, die stacked, or multi-layer die stacked). In various embodiments, die 114 may include, or be a part of, one or more of a central processing unit (CPU), a memory device (e.g., a high-bandwidth memory device), a logic circuit, input/output circuitry, a transceiver such as a field programmable gate array transceiver, a gate array logic such as a field programmable gate array logic, of a power delivery circuitry, a III-V or a III-N device such as a III-N or III-N amplifier (e.g., GaN amplifier), Peripheral Component Interconnect Express (PCIe) circuitry, Double Data Rate (DDR) transfer circuitry, or other electronic components known in the art. In some embodiments, die 114-1 and die 114-2 may comprise different functionalities. As used herein, the term “functionality” with reference to a die refers to one or more functions (e.g., capability, task, operation, action, instruction execution, etc.) that the die in question can perform. For example, die 114-1 may be a CPU or a Graphics Processing Unit (GPU) and die 114-2 may be memory. In other embodiments, die 114-1 and die 114-2 may comprise the same or similar functionalities. For example, die 114-1 and die 114-2 may each comprise memory.

In particular, dies 114-1 in layer 130-1 may be coupled to dies 114-2 in layer 130-2 by hybrid bond layers 106-1, 106-2 and compensation layers 180-1, 180-2. Conductive contacts 124 of die 114-1 may be misaligned with (e.g., offset from) conductive contacts 122 of dies 114-2 by various distances, for example, offset distances of 191, 192, 193, 194, 195, 196, 197, 198. In some embodiments, one or more of the offset distances 191, 192, 193, 194, 195, 196, 197, 198 may have an equal, or a same, distance. In some embodiments, the offset distances 191, 192, 193, 194, 195, 196, 197, 198 may be different (e.g., have a different width (i.e., y-axis distance), have a different length (i.e., x-axis distance), and/or have a different rotation (i.e., pivot angle along the xy-axis)).

A compensation layer 180 may include a conductive pathway 108 (e.g., conductive pad 108B) through a dielectric material 112. In some embodiments, a conductive pathway 108 may include a conductive pad 108B and may further include a conductive feature 108A (e.g., a conductive via or a conductive trace, which are illustrated as conductive feature 108A). As used herein, the terms “conductive feature,” “conductive via,” and “conductive trace” may be used interchangeably and refer to element 108A in the accompanying drawings. A compensation layer 180 may be formed after the layers 130-1, 130-2 of reconstituted KGWs (e.g., dies 114-1, 114-2, respectively) are inspected and the misalignment (e.g., offset distances 191-198) of the conductive contacts 124 of dies 114-1 to conductive contacts 122 of dies 114-2 are quantified. Subsequent to quantifying the misalignment of each set of conductive contacts 124, 122, the compensation layer 180 may be formed to compensate for the misalignment (e.g., offset distances 191-198) of each set of conductive contacts 124, 122. For small misalignments, a single compensation layer 180 (e.g., as shown in FIG. 7) may be sufficient. For large misalignments, two or more compensation layers 180 (e.g., as shown in FIGS. 3, 5, and 6) may be required. In particular, as shown in FIG. 3, a microelectronic assembly 100 may include a first compensation layer 180-1, on the dies 114-1 of layer 130-1, having a conductive via 108A-1 and a conductive pad 108B-1 coupled to a conductive contact 124 and a second compensation layer 180-2, on the dies 114-2 of the layer 130-2, having a conductive via 108A-2 and a conductive pad 108B-2 coupled to a conductive contact 122, where the conductive vias 108A-1, 108A-2 and conductive pads 108B-1, 108B-2 are positioned to offset a misalignment of a set of conductive contacts 124, 122. An offset distance (e.g., 191-198) and position may vary for each set of conductive contacts 124, 122, and may be determined after inspecting (e.g., using optical inspection equipment) the reconstituted KGWs. The compensation layers 180 may be manufactured using any suitable technique for adaptive patterning including mask based lithography, maskless lithography, laser direct write technology, among others, that may leverage adaptive patterning based inputs. For example, a compensation layer 180 may be formed using a single Damascene process (e.g., for a pad 108B only layer, as shown in FIG. 7B) or may be formed using a Dual-Damascene process (e.g., for a pad 108B and a via 108A layer, as shown in FIG. 3). A dielectric material 112 of the compensation layer 180 may include inorganic materials such as silicon dioxide, silicon nitride, silicon oxynitride, silicon oxycarbide, or silicon carbon nitride, or low-k and ultra low-k dielectric (e.g., carbon-doped dielectrics, fluorine-doped dielectrics, porous dielectrics, or organic polymer dielectrics (such as polyimide), or EMCs). A material of the conductive pathway 108 may include a metal, such as copper, and may be created using, for example, a Damascene process or a Dual-Damascene processes. In an example where a polymer dielectric or an EMC is used, patterning and metal electroplating steps may be followed by encapsulation of the metal interconnect pads, vias, traces with the polymer dielectric or EMC, and then planarized to reveal the interconnects. Although FIG. 3 shows conductive pathways 108 of a compensation layer 180 including conductive vias 108A and conductive pads 108B, conductive pathways 108 may include any suitable conductive features, such as conductive traces 108A and conductive pads 108B, or may include only conductive pads 108B. In some embodiments, the dies 114-1, 114-2 may include vias coupled to the conductive contacts 124, 122 such that the compensation layers 180-1, 180-2 may include only conductive pads 108B.

HB interconnect 106 generally includes an HB layer 106-1 of metal contacts 107-1, also referred to herein as “metal pads” or “HB pads,” surrounded by a dielectric material 105-1 coupled to another HB layer 106-2 of metal contacts 107-2 surrounded by the dielectric material 105-2, where the metal contacts 107 are bonded together, and the dielectric materials 105 are bonded together by fusion bonds (e.g., oxide-oxide bonds). A HB process generally uses inorganic dielectric materials, such as silicon dioxide, silicon nitride, silicon oxynitride, silicon oxycarbide, silicon carbon nitride, and/or other forms of inorganic dielectric materials or organic dielectric materials. As used herein, the term “fusion bond” is representative of bonds between a wide variety of inorganic materials typically encountered as dielectric materials in semiconductor processing and may include bonds between oxides, nitrides, carbides, oxy-nitrides, oxy-carbo-nitrides, polyimide, etc. The top surfaces of the HB pads 107 may be substantially coplanar with the top surface of the dielectric material 105. In some instances, the top surface of the HB pads 107 may be one to several nanometers below the top surface of the dielectric material 105. To initiate the bonding, the pair of HB layers 106-1, 106-2 are brought into contact with each other. At substantially room temperature, the dielectric layers 105-1, 105-2 begin to bond to each other due to Van-der-Waals forces. The temperature may then be increased. This leads to stronger covalent bonds forming between the bonding layer dielectrics herein referred to as fusion bond. This also leads to the metal pads 107-1, 107-2 that may have been slightly recessed, as mentioned, to touch since the coefficient of thermal expansion of the metal (e.g., copper) is higher than that of the surrounding dielectric. This contact and the added temperature then cause interdiffusion between the HB pads 107-1, 107-2 on opposite dies. In some embodiments, the interdiffusion may even result in there being no discernable interface between the HB pads 107-1, 107-2. That is, the HB pads 107-1, 107-2 may substantially merge to form a single conductive structure.

The HB layer 106-1 may be coupled to the compensation layer 180-1 and the HB layer 106-2 may be coupled to the compensation layer 180-2. The compensation layers 180-1, 180-2 may provide for the HB pads 107-1, 107-2 of the HB layers 106-1, 106-2, respectively, to align and bond by compensating for any misalignment created by the die bonder.

HB processes are particularly beneficial in multi-die modules because they can allow for extremely high-density interconnects. In some embodiments, a pitch of the HB interconnects may be between 50 nanometers and 10 microns. For example, a pitch of the HB interconnects may be between 50 nanometers and 3 microns. As such, extremely high input/output (I/O) densities can be provided to increase bandwidth capabilities.

During manufacture of microelectronic assembly 100, KGDs (e.g., dies 114-1, 114-2) are reconstituted on respective carrier wafers to form KGWs (e.g., layers 130-1, 130-2), where the KGDs are misaligned when overlaid for bonding. For example, using a die bonder or other similar equipment, dies 114-1 may be placed on a first carrier wafer and dies 114-2 may be placed on a second carrier wafer at locations corresponding to their respective HB interconnects. Due to equipment placement limitations (e.g., approximately 3 sigma of 500 nanometers in current generation die bonders), the respective connections of the die 114-1 and the die 114-2 are likely to be misaligned. Typically, HB pad 107 size and spacing between adjacent pads is equal to approximately one-half of a pitch of the interconnects. For example, for interconnects having a pitch equal to approximately 1 micron, the HB pad size will be approximately 500 nanometers and spacing between adjacent HB pads 107 will be approximately 500 nanometers. Using a die placement accuracy of 200 nanometers to 500 nanometers, there is a very high likelihood that opens and shorts will occur in interconnects such that all microelectronic assemblies 100 will fail. By inspecting and quantifying the misalignment of interconnects, one or more compensation layers 180 may be formed using adaptive patterning to realign the interconnects for KGW to KGW hybrid bonding, such that the reconstituted KGWs resemble unsingulated wafers where interconnects are aligned. Further, the configuration as described herein enables wafer to wafer HB bonding compatible with wafer-level tools. The HB layers 106 may be formed on the surfaces of the compensation layers 180, or if only a single compensation layer is used, on the surface of the KGWs and the assembly may undergo HB processing to form HB interconnects. The surfaces of the KGWs are amenable to be polished by chemical mechanical polishing (CMP) before bonding, thus providing high yields in wafer to wafer HB processes, and aligning the HB bond pads in the HB bonding layers for forming HB interconnects. The degree of alignment error between KGWs may assist in determining whether the compensation layer 180 includes a single Damescene layer, a Dual Damascene layer, or multiple Damascene/Dual Damascene layers. The process of forming microelectronic assemblies 100 including compensation layers 180 is described further below in reference to FIG. 8. The configuration of microelectronic assembly 100 as described herein shows the die 114-1 of layer 130-1 coupled to die 114-2 of layer 130-2 in a front-to-back hybrid bonding configuration where an active side (e.g., metallization stack 103) of die 114-2 is coupled to an active side (e.g., metallization stack 103) of die 114-1.

The microelectronic assembly 100 of FIG. 3 may also include a package substrate 102 and a circuit board 131. In particular, a package substrate 102 may be coupled to the layer 130-1 by interconnects 150 and the circuit board 131 may be coupled to the package substrate 102 by interconnects 190. Interconnects 150, 190 disclosed herein may take any suitable form including, for example, solder balls for a ball grid array arrangement, pins in a pin grid array arrangement or lands in a land grid array arrangement. In some embodiments, a set of interconnects 150, 190 may include solder (e.g., solder bumps or balls that are subject to a thermal reflow to form the interconnects 150, 190). In some embodiments, an underfill material (not shown) may extend around the associated interconnects 150, 190. The package substrate 102 may include an insulating material (e.g., a dielectric material formed in multiple layers, as known in the art) and one or more conductive pathways to route power, ground, and signals through the dielectric material. The circuit board 131 may be a motherboard, for example, and may have other components attached to it. The circuit board may include conductive pathways and other conductive contacts for routing power, ground, and signals through the circuit board, as known in the art. In some embodiments, the interconnects 190 may not couple to a circuit board 131, but may instead couple to another IC package, an interposer, or any other suitable component.

In some embodiments, one or more levels of solder resist (e.g., epoxy liquid, liquid photoimageable polymers, dry film photoimageable polymers, acrylics, solvents) may be provided in an IC package described herein and may not be labeled or shown to avoid cluttering the drawings. Solder resist may be a liquid or dry film material including photoimageable polymers. In some embodiments, solder resist may be non-photoimageable.

Although FIG. 3 depicts a microelectronic assembly 100 having a particular number and arrangement of dies 114, compensation layers 180, and HB layers 106, this number and arrangement is simply illustrative. Many of the elements of the microelectronic assembly 100 of FIG. 3 are included in other ones of the accompanying drawings; the discussion of these elements is not repeated when discussing these drawings, and any of these elements may take any of the forms disclosed herein. Further, a number of elements are illustrated in FIG. 3 as included in the microelectronic assembly 100, but a number of these elements may not be present in a microelectronic assembly 100. For example, in various embodiments, the package substrate 102 and circuit board 131 may not be included.

FIG. 4A is a schematic of stacked views of two dies and two compensation layers for bonding together according to some embodiments of the present disclosure. Assembly 401 includes a die 114-1 having conductive contacts 124 overlaid on a die 114-2 having conductive contacts 122. The dies 114-1, 114-2 may be KGDs reconstituted on wafer carriers to form respective KGWs. As shown in FIG. 4A, the dies 114-1, 114-2 are misplaced such that the sets of conductive contacts 124, 122 are misaligned along a width (e.g., y-direction), a length (e.g., x-direction), and/or an angle of rotation (e.g., theta (O)). The sets of conductive contacts 124, 122 may be misaligned by different widths, lengths, and/or angles of rotation. In fact, as shown in assembly 401, the conductive contacts 124 of the die 114-1 and the conductive contacts 122 of the die 114-2 are misaligned such that an interconnect may not be formed, or an interconnect may be formed improperly with a neighboring contact. Assembly 402 illustrates the assembly 401 further including a first compensation layer (e.g., the compensation layer 180-1 of FIG. 3) having first conductive vias 108A-1 and first conductive pads 108B-1 that at least partially offset the misaligned conductive contacts 124, 122. The first conductive vias 108A-1 and the first conductive pads 108B-1 may have different dimensions and different offset values depending on the determined misalignments between each set of conductive contacts 124, 122. Assembly 403-1 illustrates the assembly 402 further including a second compensation layer (e.g., the compensation layer 180-2 of FIG. 3) having second conductive vias 108A-2 and second conductive pads 108B-2 that at least partially offset the misaligned conductive contacts 124, 122. The second conductive vias 108A-2 and the second conductive pads 108B-2 may have different dimensions and different offset values depending on the determined misalignments between each set of conductive contacts 124, 122 as well as based on the partial offset provided by the first conductive vias 108A-1 and the first conductive pads 108B-1 of the first compensation layer. In some embodiments, the first conductive vias 108A-1 and first conductive pads 108B-1 have similar dimensions and offset distances as the second conductive vias 108A-2 and second conductive pads 108B-2. In some embodiments, the first conductive vias 108A-1 and first conductive pads 108B-1 have different dimensions and different offset distances as compared to the second conductive vias 108A-2 and second conductive pads 108B-2, such that the first compensation layer offsets misalignments more aggressively than the second compensation layer or vice versa.

FIG. 4B is a schematic of other stacked views of two dies and two compensation layers for bonding together according to some embodiments of the present disclosure. FIG. 4B shows an assembly 403-2 and 403-3, which are similar to the assembly 403-1 of FIG. 4A, except for differences as described further. Assembly 403-2 includes a first compensation layer (e.g., the compensation layer 180-1 of FIG. 3) and a second compensation layer (e.g., the compensation layer 180-2 of FIG. 3). The first compensation layer having first conductive traces 108A-1 and first conductive pads 108B-1 that at least partially offset the misaligned conductive contacts 124, 122. The second compensation layer having second conductive traces 108A-2 and second conductive pads 108B-2 that offset the misaligned conductive contacts 124, 122. The first conductive traces 108A-1 and the first conductive pads 108B-1 may have different dimensions and different offset values depending on the determined misalignments between each set of conductive contacts 124, 122. The second conductive traces 108A-2 and the second conductive pads 108B-2 may have different dimensions and different offset values depending on the determined misalignments between each set of conductive contacts 124, 122 as well as based on the partial offset provided by the first conductive traces 108A-1 and the first conductive pads 108B-1 of the first compensation layer. In some embodiments, the first conductive traces 108A-1 and first conductive pads 108B-1 have similar dimensions and offset distances as the second conductive traces 108A-2 and second conductive pads 108B-2. In some embodiments, the first conductive vias 108A-1 and first conductive pads 108B-1 have different dimensions and different offset distances as compared to the second conductive vias 108A-2 and second conductive pads 108B-2, such that the first compensation layer offsets misalignments more aggressively than the second compensation layer or vice versa.

Assembly 403-3 includes a first compensation layer (e.g., the compensation layer 180-1 of FIG. 3) having first conductive pads 108B-1 and a second compensation layer (e.g., the compensation layer 180-2 of FIG. 3) having second conductive pads 108B-2 that offset the misaligned conductive contacts 124, 122. As shown in assembly 403-3, the first compensation layer only includes first conductive pads 108B-1 and the second compensation layer only includes second conductive pads 108B-2 (e.g., as shown for compensation layer 180 in FIG. 7B). The first conductive pads 108B-1 and second conductive pads 108B-2 may have different dimensions and different offset values depending on the determined misalignments between each set of conductive contacts 124, 122.

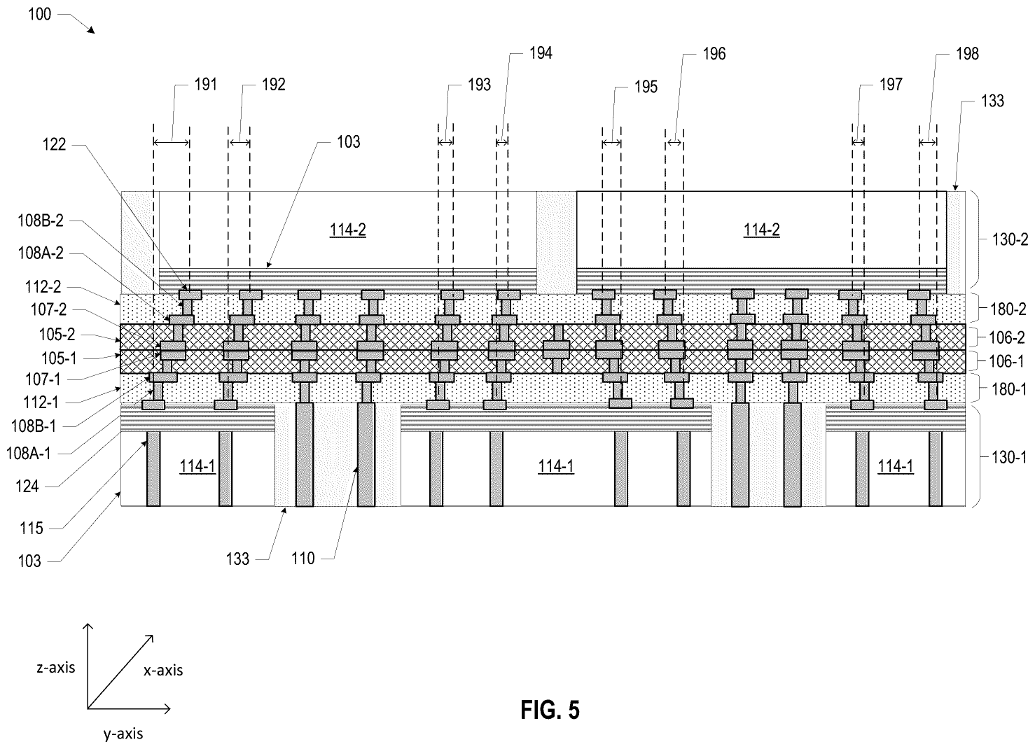

FIG. 5 is a schematic cross-sectional view of another example microelectronic assembly according to some embodiments of the present disclosure. The configuration of the embodiment shown in the figure is like that of FIG. 3, except for differences as described further. The configuration of microelectronic assembly 100 as described herein shows the die 114-1 of layer 130-1 coupled to die 114-2 of layer 130-2 in a front-to-front hybrid bonding configuration where an active side (e.g., metallization stack 103) of die 114-2 is coupled to an active side (e.g., metallization stack 103) of die 114-1.

FIG. 6A is a schematic cross-sectional view of another example microelectronic assembly according to some embodiments of the present disclosure. The configuration of the embodiment shown in the figure is like that of FIG. 3, except for differences as described further. The configuration of microelectronic assembly 100, in the embodiment shown, may include a stack of layers 130 (e.g., 130-1, 130-2) coupled by two compensation layers (e.g., 180-1A, 180-1B) and hybrid bonding (HB) interconnects 106. The two compensation layers 180-1A, 180-1B are between the layer 130-1 and the HB layer 106-1, and there is no compensation layer 180 between the layer 130-2 and HB layer 106-2. The die 114-1 of layer 130-1 are coupled to die 114-2 of layer 130-2 in a back-to-back configuration where a back side of die 114-2 is coupled to a back side of die 114-1. Layer 130-2 may further include a via 110 that extends through the insulating material 133 of the layer 130-2 that is coupled to the die 114-1 in the layer 130-1 by conductive pathways 108 through the compensation layers 180-1A, 180-1B.

FIG. 6B is a schematic cross-sectional view of another example microelectronic assembly according to some embodiments of the present disclosure. The configuration of the embodiment shown in the figure is like that of FIG. 6A, except for differences as described further. The configuration of microelectronic assembly 100, in the embodiment shown, may include a third layer 130-3 of dies 114-3 in the stack of layers (e.g., 130-1, 130-2) where each adjacent layer in the stack of layers is coupled by compensation layers (e.g., 180-1A, 180-1B, 180-2, 180-3) and hybrid bonding (HB) interconnects 106 of hybrid bond layers (e.g., 106-1, 106-2, and 106-3, 106-4). The dies 114-3 may include KGDs reconstituted to form a KGW. Although FIG. 6B illustrates a particular number and arrangement of compensation layers 180, a microelectronic assembly may include any suitable number and arrangement of compensation layers 180.

FIG. 7A is a schematic cross-sectional view of another example microelectronic assembly according to some embodiments of the present disclosure. The configuration of the embodiment shown in the figure is like that of FIG. 3, except for differences as described further. The configuration of microelectronic assembly 100, in the embodiment shown, may include a stack of layers 130 (e.g., 130-1, 130-2) coupled by a compensation layer 180 and hybrid bonding (HB) interconnects 106. The compensation layer 180 is between the layer 130-1 and the HB layer 106-1, and there is no compensation layer 180 between the layer 130-2 and HB layer 106-2. Layer 130-2 may include a wafer 113 that has not been singulated (e.g., not reconstituted with KGDs). The wafer 113 may include metallization layers that have conductive contacts 122 with different pitches. For example, as shown, wafer 113 may include first conductive contacts 122-1 have a first pitch, second conductive contacts 122-2 having a second pitch different than the first pitch, and third conductive contacts 122-3 having a third pitch different than the first pitch and the second pitch. Individual conductive contacts 124, 122 may be coupled to individual HB pads 107-1, 107-2, respectively, or, as shown for the third conductive contacts 122-3, an individual conductive contact 122 may be coupled to two or more HB pads 107-2. The microelectronic assembly 100 of FIG. 7 may include a single compensation layer 180 due to the reduced offset 791, 792 between conductive contacts 122-1, 122-2 and conductive contacts 124, respectively. In some embodiments, the wafer 113 may include a plurality of reconstituted KGDs.

FIG. 7B is a schematic cross-sectional view of another example microelectronic assembly according to some embodiments of the present disclosure. The configuration of the embodiment shown in the figure is like that of FIG. 7A, except for differences as described further. The configuration of microelectronic assembly 100, in the embodiment shown, may include a stack of layers 130 (e.g., 130-1, 130-2) coupled by a compensation layer 180 and hybrid bonding (HB) interconnects 106. The compensation layer 180 may include conductive pads 108B and may not include conductive vias (e.g., conductive vias 108A, as shown in FIG. 7A). The compensation layer 180 including only conductive pads 108B may be formed using any suitable process, such as a single Damascene process.

In various embodiments, any of the features discussed with reference to any of FIGS. 2-7 herein may be combined with any other features to form a package with one or more IC dies as described herein, for example, to form a modified microelectronic assembly 100. Some such combinations are described above, but, in various embodiments, further combinations and modifications are possible.

### Example Methods

FIGS. 8A-8E are schematic cross-sectional views of various stages of manufacture of an example microelectronic assembly 100 according to some embodiments of the present disclosure. FIG. 8A illustrates assemblies 801-1, 801-2. Assembly 801-1 may include a carrier 800-1 with dies 114-1 (e.g., dies 114-1A, 114-1B, 114-1C) reconstituted thereon. Dies 114-1 may be KGDs and may include a substrate 109, a metallization stack 103, and through-silicon vias (TSVs) 115 coupling conductive contacts 124 to the metallization stack 103. Assembly 801-2 may include a carrier 800-2 with dies 114-2 (e.g., dies 114-2A, 114-2B) reconstituted thereon. Dies 114-2 may be KGDs and may include a substrate 109 and a metallization stack 103 coupled to conductive contacts 122. Carriers 800-1, 800-2 may include any suitable material for providing mechanical stability during manufacturing operations, and in some embodiments, may include a semiconductor wafer (e.g., a silicon wafer) or glass. In some embodiments, the assembly 801-1 or the assembly 801-2 may be an unsingulated wafer. The dies 114-1, 114-2 may be placed using any suitable technique, such as a die bonder.

FIG. 8B illustrates assemblies 802-1, 802-2 subsequent to forming layers 130-1, 130-2, respectively, by depositing an insulating material 133 on and around the dies 114-1, 114-2. The insulating material 133 may include any suitable material, as described above with reference to FIG. 3, and may be deposited using any suitable technique, for example, using a Plasma Enhanced Chemical Vapor Deposition (PECVD) process or a spin coating process. In some embodiments, a liner material (not shown), such as silicon nitride or silicon carbon nitride, may be coated on and around the dies 114-1, 114-2 prior to depositing the insulating material 133. The liner material may be deposited using any suitable technique, such as atomic layer deposition (ALD), chemical vapor deposition (CVD), or PECVD. In some embodiments, an insulating material 133 may be deposited to completely cover the dies 114-1, 114-2 and the overburden of insulating material 133 may be removed to expose conductive contacts 124, 122 on a top surface of the dies 114-1, 114-2, respectively. The insulating material 133 may be removed using any suitable technique, including mechanical grinding and/or CMP. Layer 130-1 may further include a via 110 that extends through the insulating material 133. Layer 130-2 may further include a via 110 (not shown) that extends through the insulating material 133. The via 110 may be formed using any suitable technique, including additive or subtractive processes. In some embodiments, the via 110 may be formed prior to depositing the insulating material 133. In some embodiments, the via 110 may be formed subsequent to depositing the insulating material 133.

FIG. 8C illustrates assemblies 803-1, 803-2 subsequent to forming compensation layers 180-1, 180-2 on the top surfaces of the assemblies 802-1, 802-2 of FIG. 8B. The compensation layers 180 may include a dielectric material 112 with conductive pathways 108 (e.g., conductive vias 108A and conductive pads 108B) that are offset in a direction to compensate for misalignment of the dies 114-1, 114-2. The assemblies 802-1, 802-2 in FIG. 8B may be optically inspected to quantify any misalignment vectors of the dies 114-1, 114-2 on the carriers 800-1, 800-2 (e.g., true position), and, thus, misalignment vectors of the individual sets of conductive contacts 124, 122. The determined misalignment quantifications may be used to pattern compensation layers 180-1, 180-2 and correct the misalignments (e.g., compensate for the offsets). For example, the compensation layer 180-1 may include a first conductive pathway 108 with an offset 891 that moves an interconnection of die 114-1A in a first direction (e.g., in a positive y-direction or to the right), a second conductive pathway 108 with an offset 892 that moves an interconnection of die 114-1B in the first direction, a third conductive pathway 108 with an offset 893 that moves an other interconnection of die 114-1B in a second direction (e.g., in a negative y-direction or to the left), and a fourth conductive pathway 108 with an offset 894 that moves the interconnection of die 114-1C in the second direction.

The conductive pathways 108 of the compensation layer 180 may be mapped to offset interconnect misalignments between the dies 114-1, 114-2, and, as such, may be designed to have different sizes, different distances, and/or different directions from each other. For example, the compensation layer 180-1 may include the first conductive pathway 108 with an offset 891 that moves an interconnection of die 114-1A in a first direction by a first dimension, a second conductive pathway 108 with an offset 892 that moves an interconnection of die 114-1B in the first direction by a second dimension different than the first dimension, a third conductive pathway 108 with an offset 893 that moves an other interconnection of die 114-1B in a second direction different from the first direction by a third dimension different from the first and second dimensions, and a fourth conductive pathway 108 with an offset 894 that moves the interconnection of die 114-1C in the second direction by a fourth dimension different than the first, second, and third dimensions.

In another example, the compensation layer 180-1 may include a first conductive pathway 108 that moves an interconnection of a first die 114-1 in a first direction by a first dimension, a second conductive pathway 108 that moves an interconnection of a second die 114-1 in a second direction by a second dimension, a third conductive pathway 108 that moves an other interconnection of the second die 114-1 in a third direction by a third dimension, and a fourth conductive pathway 108 that moves the interconnection of a third die 114-1 in a fourth direction by a fourth dimension, where the first, second, third, and fourth directions are different than each other and the first, second, third, and fourth dimensions are different than each other.

In yet another example, the compensation layer 180-1 may include a conductive pathway 108 that moves an interconnection of die 114-1 in a first direction by a first dimension and in a second direction by a second dimension, where the first and second directions are different, and the first and second dimensions have a same value or have different values. In some embodiments, the compensation layer 180-1 may include a first conductive pathway 108 that moves an interconnection of die 114-1 in a direction that is a rotational direction. The conductive pathways 108 in the compensation layer 180-2 of assembly 803-2 may have similar offsets in similar directions as the assembly 803-1, or may have different offsets (e.g., smaller offsets or larger offsets) in similar directions as the assembly 803-1 based on the misplacement of the individual die or dies. The compensation layers 180-1, 180-2 may be formed using any suitable technique, including the techniques described above with reference to FIG. 3. For example, the compensation layers 180 may be formed using a BEOL process. In some embodiments, the compensation layers 180 may be formed using an adaptive patterning process, such as direct write lithography. In some embodiments, alignment marks may be patterned and fabricated on the dies 114, the insulating material 133, and/or the compensation layers 180 to assist with aligning the dies 114.

FIG. 8D illustrates assemblies 804-1, 804-2 subsequent to forming a HB layer 106 (e.g., HB layers 106-1, 106-2) on top surfaces of the assemblies 803-1, 803-2 of FIG. 8C. The HB layer 106-1 may include bond-pads 107-1 in a dielectric material 105-1 and HB layer 106-2 may include bond-pads 107-2 in a dielectric material 105-2. The bond pads 107-1 of HB layer 106-1 may correspond to bond-pads 107-2 of HB layer 106-2, as described above with reference to FIG. 3, for forming HB interconnects. In some embodiments, a pitch of the HB interconnects is between 50 nanometers and 10 microns.

FIG. 8E illustrates a microelectronic assembly 100 subsequent to inverting the assembly 804-2 of FIG. 8D, removing the carriers 800-1, 800-2 from assemblies 804-1, 804-2 of FIG. 8D, and forming HB interconnects. The assembly of FIG. 8E may be subjected to appropriate bonding process to form HB interconnects, as described above with reference to FIG. 3. The HB interconnects may be formed where the conductive bond pads align. The HB interconnects may include multiple pitches as well as non-uniform pitches. The microelectronic assembly 100 may be manufactured together with other assemblies, and if manufactured with other assemblies, the assemblies may be singulated. The assembly of FIG. 8E may itself be a microelectronic assembly 100, as shown. Further manufacturing operations may be performed on the microelectronic assembly 100 of FIG. 8E to form other microelectronic assembly 100; for example, the microelectronic assembly 100 of FIG. 8E may be coupled to a package substrate 102 by interconnects 150 and the package substrate 102 may be coupled to a circuit board 131 by interconnects 190, similar to the microelectronic assembly 100 of FIG. 3.

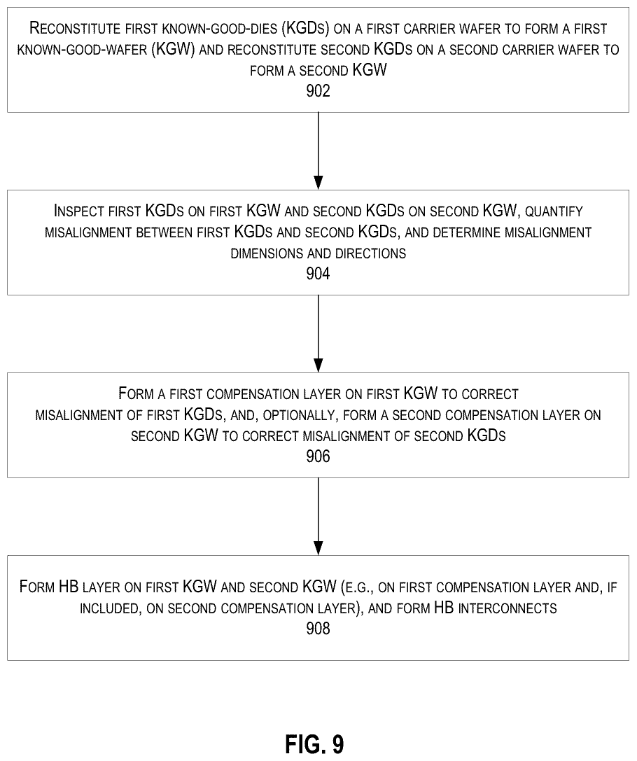

FIG. 9 is a flow diagram of an example method of fabricating an example microelectronic assembly 100 of FIGS. 3 and 5-7, in accordance with various embodiments. At 902, first dies 114-1 (e.g., KGDs) may be reconstituted on a first wafer carrier to form layer 130-1 (e.g., a first KGW) and second dies 114-2 (e.g., KGDs) may be reconstituted on a second wafer carrier to form layer 130-2 (e.g., a second KGW). First dies 114-1 and second dies 114-2 may be placed using any suitable technique, such as a die bonder. A liner material may be deposited on and over the first dies 114-1 and the second dies 114-2, and an insulating material 133 may be deposited on the liner material. The insulating material 133 may be planarized to expose conductive contacts 124 on a surface of the first dies 114-1 and conductive contacts 122 on a surface of the second dies 114-2. In some embodiments, a second wafer may include an unsingulated wafer of second dies 114-2.

At 904, the first dies 114-1 may be inspected, for example, optically imaged, to establish the true placement of the first dies 114-1 and the second dies 114-2, and any misplacement (e.g., misalignment) may be quantified. The quantified misplacement may provide an offset value (e.g., length, width, and/or a rotational offset value) for each of the first dies 114-1 and the second dies 114-2 (e.g., for each of the respective set of conductive contacts 122, 124). The determined offset values may be used in subsequent operations to provide adaptive patterning to accommodate and compensate the offsets.

At 906, a first compensation layer 180 having conductive pathways 108 may be formed on the first dies 114-1 (e.g., on the surface of the first layer 130-1) to correct for the misplacement of the first dies 114-1 and/or the second dies 114-2. The quantified offset values may be used to account for inaccuracies in the placement of dies 114. In some embodiments, a compensation layer 180 may be fabricated using an adaptive patterning process, such as direct write lithography or maskless lithography, etc. In some embodiments, a single compensation layer 180 may be formed on the layer 130-1. In some embodiments, two or more compensation layers 180 may be formed on the layer 130-1. In some embodiments, a compensation layer 180 may include conductive pads 108B. In some embodiments, a compensation layer 180 may include conductive pads 108B and conductive vias 108A or conductive traces 108A. In some embodiments, a second compensation layer 180 may be formed on the layer 130-2. In some embodiments, two or more compensation layers 180 may be formed on the layer 130-2.

At 908, HB layers 106-1, 106-2 may be formed on a top surface of layers 130-1, 130-2, respectively, (e.g., on the compensation layers 180-1 and 180-2, if included). HB layers 106-1, 106-2 may include a dielectric material 105-1, 105-2 and HB pads 107-1, 107-2, respectively. HB pads 107-1 of the HB layer 106-1 may align with HB pads 107-2 of HB layer 106-2 and HB interconnects may be formed. The conductive contacts 124 of the first dies 114-1 may be coupled to the respective conductive contacts 122 of the second dies 114-2 by the conductive pathways 108 in the compensation layer 180 and the HB interconnects.

### Example Devices and Components

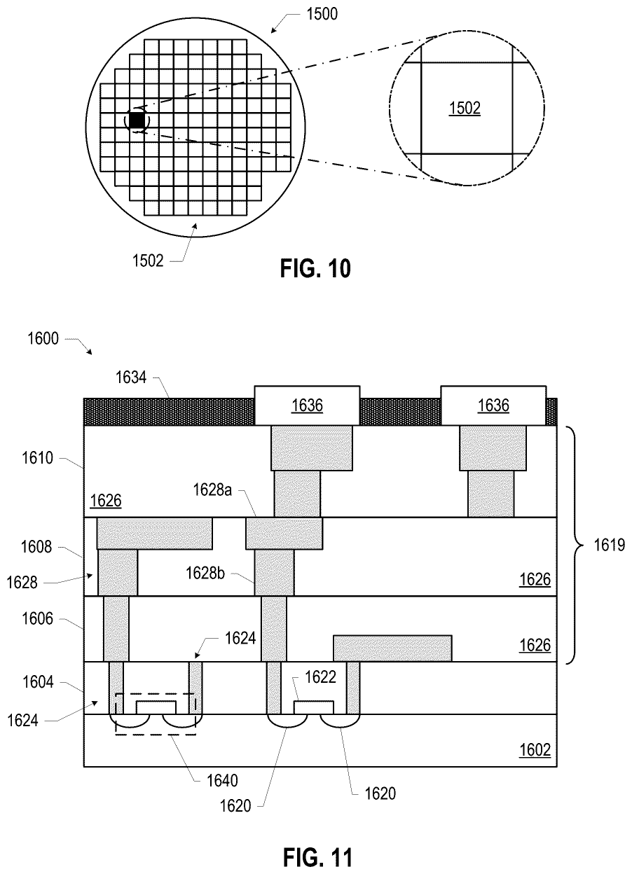

The microelectronic assemblies 100 disclosed herein may be included in any suitable electronic component. FIGS. 10-14 illustrate various examples of apparatuses that may include, or be included in, any of the microelectronic assemblies 100 disclosed herein.

FIG. 10 is a top view of a wafer 1500 and dies 1502 that may be included in any of the microelectronic assemblies 100 disclosed herein (e.g., as any suitable ones of the dies 114). The wafer 1500 may be composed of semiconductor material and may include one or more dies 1502 having IC structures formed on a surface of the wafer 1500. Each of the dies 1502 may be a repeating unit of a semiconductor product that includes any suitable IC. After the fabrication of the semiconductor product is complete, the wafer 1500 may undergo a singulation process in which the dies 1502 are separated from one another to provide discrete “chips” of the semiconductor product. The die 1502 may be any of the dies 114 disclosed herein. The die 1502 may include one or more transistors (e.g., some of the transistors 1640 of FIG. 11, discussed below), supporting circuitry to route electrical signals to the transistors, passive components (e.g., signal traces, resistors, capacitors, or inductors), and/or any other IC components. In some embodiments, the wafer 1500 or the die 1502 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 14) or other logic that is configured to store information in the memory devices or execute instructions stored in the memory array. In some embodiments, a die 1502 (e.g., a die 114) may be a central processing unit, a radio frequency chip, a power converter, or a network processor. Various ones of the microelectronic assemblies 100 disclosed herein may be manufactured using a die-to-wafer assembly technique in which some dies 114 are attached to a wafer 1500 that include others of the dies 114, and the wafer 1500 is subsequently singulated.

FIG. 11 is a cross-sectional side view of an IC device 1600 that may be included in any of the microelectronic assemblies 100 disclosed herein (e.g., in any of the dies 114). One or more of the IC devices 1600 may be included in one or more dies 1502 (FIG. 10). The IC device 1600 may be formed on a die substrate 1602 (e.g., the wafer 1500 of FIG. 10) and may be included in a die (e.g., the die 1502 of FIG. 10). The die substrate 1602 may be a semiconductor substrate composed of semiconductor material systems including, for example, n-type or p-type materials systems (or a combination of both). The die substrate 1602 may include, for example, a crystalline substrate formed using a bulk silicon or a silicon-on-insulator (SOI) substructure. In some embodiments, the die substrate 1602 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1602. Although a few examples of materials from which the die substrate 1602 may be formed are described here, any material that may serve as a foundation for an IC device 1600 may be used. The die substrate 1602 may be part of a singulated die (e.g., the dies 1502 of FIG. 10) or a wafer (e.g., the wafer 1500 of FIG. 10).

The IC device 1600 may include one or more device layers 1604 disposed on the die substrate 1602. The device layer 1604 may include features of one or more transistors 1640 (e.g., metal oxide semiconductor field-effect transistors (MOSFETs)) formed on the die substrate 1602. The device layer 1604 may include, for example, one or more source and/or drain (S/D) regions 1620, a gate 1622 to control current flow in the transistors 1640 between the S/D regions 1620, and one or more S/D contacts 1624 to route electrical signals to/from the S/D regions 1620. The transistors 1640 may include additional features not depicted for the sake of clarity, such as device isolation regions, gate contacts, and the like. The transistors 1640 are not limited to the type and configuration depicted in FIG. 11 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1640 may include a gate 1622 formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1640 is to be a PMOS or a NMOS transistor. In some implementations, the gate electrode may consist of a stack of two or more metal layers, where one or more metal layers are work function metal layers and at least one metal layer is a fill metal layer. Further metal layers may be included for other purposes, such as a barrier layer. For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1640 along the source-channel-drain direction, the gate electrode may consist of a U-shaped structure that includes a bottom portion substantially parallel to the surface of the die substrate 1602 and two sidewall portions that are substantially perpendicular to the top surface of the die substrate 1602. In other embodiments, at least one of the metal layers that form the gate electrode may simply be a planar layer that is substantially parallel to the top surface of the die substrate 1602 and does not include sidewall portions substantially perpendicular to the top surface of the die substrate 1602. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1620 may be formed within the die substrate 1602 adjacent to the gate 1622 of each transistor 1640. The S/D regions 1620 may be formed using an implantation/diffusion process or an etching/deposition process, for example. In the former process, dopants such as boron, aluminum, antimony, phosphorous, or arsenic may be ion-implanted into the die substrate 1602 to form the S/D regions 1620. An annealing process that activates the dopants and causes them to diffuse farther into the die substrate 1602 may follow the ion-implantation process. In the latter process, the die substrate 1602 may first be etched to form recesses at the locations of the S/D regions 1620. An epitaxial deposition process may then be carried out to fill the recesses with material that is used to fabricate the S/D regions 1620. In some implementations, the S/D regions 1620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1620 may be formed using one or more alternate semiconductor materials such as germanium or a group III-V material or alloy. In further embodiments, one or more layers of metal and/or metal alloys may be used to form the S/D regions 1620.

Electrical signals, such as power and/or input/output (I/O) signals, may be routed to and/or from the devices (e.g., transistors 1640) of the device layer 1604 through one or more interconnect layers disposed on the device layer 1604 (illustrated in FIG. 11 as interconnect layers 1606-1610). For example, electrically conductive features of the device layer 1604 (e.g., the gate 1622 and the S/D contacts 1624) may be electrically coupled with the interconnect structures 1628 of the interconnect layers 1606-1610. The one or more interconnect layers 1606-1610 may form a metallization stack (also referred to as an “ILD stack”) 1619 of the IC device 1600.

The interconnect structures 1628 may be arranged within the interconnect layers 1606-1610 to route electrical signals according to a wide variety of designs; in particular, the arrangement is not limited to the particular configuration of interconnect structures 1628 depicted in FIG. 11. Although a particular number of interconnect layers 1606-1610 is depicted in FIG. 11, embodiments of the present disclosure include IC devices having more or fewer interconnect layers than depicted.

In some embodiments, the interconnect structures 1628 may include lines 1628a and/or vias 1628b filled with an electrically conductive material such as a metal. The lines 1628a may be arranged to route electrical signals in a direction of a plane that is substantially parallel with a surface of the die substrate 1602 upon which the device layer 1604 is formed. For example, the lines 1628a may route electrical signals in a direction in and out of the page from the perspective of FIG. 11. The vias 1628b may be arranged to route electrical signals in a direction of a plane that is substantially perpendicular to the surface of the die substrate 1602 upon which the device layer 1604 is formed. In some embodiments, the vias 1628b may electrically couple lines 1628a of different interconnect layers 1606-1610 together.

The interconnect layers 1606-1610 may include a dielectric material 1626 disposed between the interconnect structures 1628, as shown in FIG. 11. In some embodiments, the dielectric material 1626 disposed between the interconnect structures 1628 in different ones of the interconnect layers 1606-1610 may have different compositions; in other embodiments, the composition of the dielectric material 1626 between different interconnect layers 1606-1610 may be the same.

A first interconnect layer 1606 (referred to as Metal 1 or “M1”) may be formed directly on the device layer 1604. In some embodiments, the first interconnect layer 1606 may include lines 1628a and/or vias 1628b, as shown. The lines 1628a of the first interconnect layer 1606 may be coupled with contacts (e.g., the S/D contacts 1624) of the device layer 1604.

A second interconnect layer 1608 (referred to as Metal 2 or “M2”) may be formed directly on the first interconnect layer 1606. In some embodiments, the second interconnect layer 1608 may include vias 1628b to couple the lines 1628a of the second interconnect layer 1608 with the lines 1628a of the first interconnect layer 1606. Although the lines 1628a and the vias 1628b are structurally delineated with a line within each interconnect layer (e.g., within the second interconnect layer 1608) for the sake of clarity, the lines 1628a and the vias 1628b may be structurally and/or materially contiguous (e.g., simultaneously filled during a dual damascene process) in some embodiments.

A third interconnect layer 1610 (referred to as Metal 3 or “M3”) (and additional interconnect layers, as desired) may be formed in succession on the second interconnect layer 1608 according to similar techniques and configurations described in connection with the second interconnect layer 1608 or the first interconnect layer 1606. In some embodiments, the interconnect layers that are “higher up” in the metallization stack 1619 in the IC device 1600 (i.e., farther away from the device layer 1604) may be thicker.

The IC device 1600 may include a solder resist material 1634 (e.g., polyimide or similar material) and one or more conductive contacts 1636 formed on the interconnect layers 1606-1610. In FIG. 11, the conductive contacts 1636 are illustrated as taking the form of bond pads. The conductive contacts 1636 may be electrically coupled with the interconnect structures 1628 and configured to route the electrical signals of the transistor(s) 1640 to other external devices. For example, solder bonds may be formed on the one or more conductive contacts 1636 to mechanically and/or electrically couple a chip including the IC device 1600 with another component (e.g., a circuit board). The IC device 1600 may include additional or alternate structures to route the electrical signals from the interconnect layers 1606-1610; for example, the conductive contacts 1636 may include other analogous features (e.g., posts) that route the electrical signals to external components.

In some embodiments in which the IC device 1600 is a double-sided die, the IC device 1600 may include another metallization stack (not shown) on the opposite side of the device layer(s) 1604. This metallization stack may include multiple interconnect layers as discussed above with reference to the interconnect layers 1606-1610, to provide conductive pathways (e.g., including conductive lines and vias) between the device layer(s) 1604 and additional conductive contacts (not shown) on the opposite side of the IC device 1600 from the conductive contacts 1636.

In other embodiments in which the IC device 1600 is a double-sided die, the IC device 1600 may include one or more TSVs through the die substrate 1602; these TSVs may make contact with the device layer(s) 1604, and may provide conductive pathways between the device layer(s) 1604 and additional conductive contacts (not shown) on the opposite side of the IC device 1600 from the conductive contacts 1636.

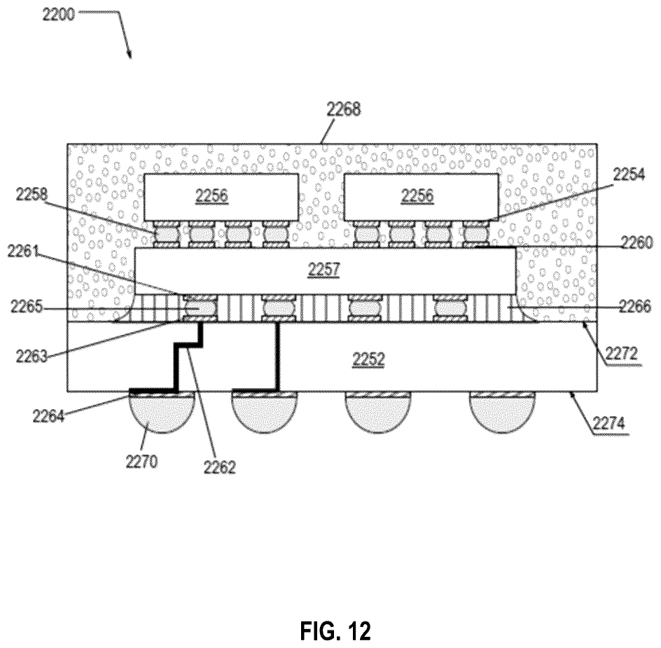

FIG. 12 is a side, cross-sectional view of an example IC package 2200 that may include microelectronic assemblies in accordance with any of the embodiments disclosed herein. In some embodiments, the IC package 2200 may be a system-in-package (SiP).

As shown in FIG. 12, package support 2252 may be formed of an insulator (e.g., a ceramic, a buildup film, an epoxy film having filler particles therein, etc.), and may have conductive pathways extending through the insulator between first face 2272 and second face 2274, or between different locations on first face 2272, and/or between different locations on second face 2274. These conductive pathways may take the form of any of the interconnect structures comprising lines and/or vias, e.g., as discussed above with reference to FIG. 1.

Package support 2252 may include conductive contacts 2263 that are coupled to conductive pathway 2262 through package support 2252, allowing circuitry within dies 2256 and/or interposer 2257 to electrically couple to various ones of conductive contacts 2264 (or to other devices included in package support 2252, not shown).

IC package 2200 may include interposer 2257 coupled to package support 2252 via conductive contacts 2261 of interposer 2257, first level interconnects (FLI) 2265, and conductive contacts 2263 of package support 2252. FLI 2265 illustrated in FIG. 12 are solder bumps, but any suitable FLI 2265 may be used, such as solder bumps, solder posts, or bond wires.

IC package 2200 may include one or more dies 2256 coupled to interposer 2257 via conductive contacts 2254 of dies 2256, FLI 2258, and conductive contacts 2260 of interposer 2257. Conductive contacts 2260 may be coupled to conductive pathways (not shown) through interposer 2257, allowing circuitry within dies 2256 to electrically couple to various ones of conductive contacts 2261 (or to other devices included in interposer 2257, not shown). FLI 2258 illustrated in FIG. 12 are solder bumps, but any suitable FLI 2258 may be used, such as solder bumps, solder posts, or bond wires. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

In some embodiments, underfill material 2266 may be disposed between package support 2252 and interposer 2257 around FLI 2265, and mold 2268 may be disposed around dies 2256 and interposer 2257 and in contact with package support 2252. In some embodiments, underfill material 2266 may be the same as mold 2268. Example materials that may be used for underfill material 2266 and mold 2268 are epoxies as suitable. Second level interconnects (SLI) 2270 may be coupled to conductive contacts 2264. SLI 2270 illustrated in FIG. 12 are solder balls (e.g., for a ball grid array (BGA) arrangement), but any suitable SLI 2270 may be used (e.g., pins in a pin grid array arrangement or lands in a land grid array arrangement). SLI 2270 may be used to couple IC package 2200 to another component, such as a circuit board (e.g., a motherboard), an interposer, or another IC package, as known in the art and as discussed below with reference to FIG. 6.

In embodiments in which IC package 2200 includes multiple dies 2256, IC package 2200 may be referred to as a multichip package (MCP). Dies 2256 may include circuitry to perform any desired functionality. For example, besides one or more of dies 2256 comprising components of dies 114 as described herein, one or more of dies 2256 may be logic dies (e.g., silicon-based dies), one or more of dies 2256 may be memory dies (e.g., high-bandwidth memory), etc. In some embodiments, at least some of dies 2256 may not include components of dies 114 as described herein.

Although IC package 2200 illustrated in FIG. 12 is a flip-chip package, other package architectures may be used. For example, IC package 2200 may be a BGA package, such as an embedded wafer-level ball grid array (eWLB) package. In another example, IC package 2200 may be a wafer-level chip scale package (WLCSP) or a panel fan-out (FO) package. Although two dies 2256 are illustrated in IC package 2200, IC package 2200 may include any desired number of dies 2256. IC package 2200 may include additional passive components, such as surface-mount resistors, capacitors, and inductors disposed over first face 2272 or second face 2274 of package support 2252, or on either face of interposer 2257. More generally, IC package 2200 may include any other active or passive components known in the art.

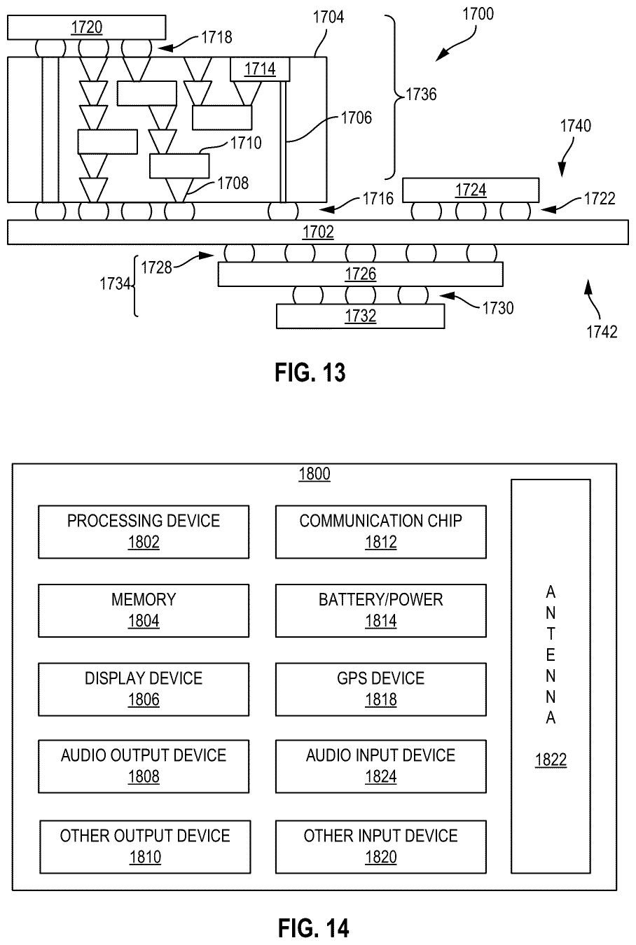

FIG. 13 is a cross-sectional side view of an IC device assembly 1700 that may include any of the microelectronic assemblies 100 disclosed herein. In some embodiments, the IC device assembly 1700 may be a microelectronic assembly 100. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. Any of the IC packages discussed below with reference to the IC device assembly 1700 may take the form of any suitable ones of the embodiments of the microelectronic assemblies 100 disclosed herein.

In some embodiments, the circuit board 1702 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate. In some embodiments the circuit board 1702 may be, for example, a circuit board.

The IC device assembly 1700 illustrated in FIG. 13 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 13), male and female portions of a socket, an adhesive, an underfill material, and/or any other suitable electrical and/or mechanical coupling structure.

The package-on-interposer structure 1736 may include an IC package 1720 coupled to an interposer 1704 by coupling components 1718. The coupling components 1718 may take any suitable form for the application, such as the forms discussed above with reference to the coupling components 1716. Although a single IC package 1720 is shown in FIG. 13, multiple IC packages may be coupled to the interposer 1704; indeed, additional interposers may be coupled to the interposer 1704. The interposer 1704 may provide an intervening substrate used to bridge the circuit board 1702 and the IC package 1720. The IC package 1720 may be or include, for example, a die (the die 1502 of FIG. 10), an IC device (e.g., the IC device 1600 of FIG. 11), or any other suitable component. Generally, the interposer 1704 may spread a connection to a wider pitch or reroute a connection to a different connection. For example, the interposer 1704 may couple the IC package 1720 (e.g., a die) to a set of ball grid array (BGA) conductive contacts of the coupling components 1716 for coupling to the circuit board 1702. In the embodiment illustrated in FIG. 13, the IC package 1720 and the circuit board 1702 are attached to opposing sides of the interposer 1704; in other embodiments, the IC package 1720 and the circuit board 1702 may be attached to a same side of the interposer 1704. In some embodiments, three or more components may be interconnected by way of the interposer 1704.

In some embodiments, the interposer 1704 may be formed as a PCB, including multiple metal layers separated from one another by layers of dielectric material and interconnected by electrically conductive vias. In some embodiments, the interposer 1704 may be formed of an epoxy resin, a fiberglass-reinforced epoxy resin, an epoxy resin with inorganic fillers, a ceramic material, or a polymer material such as polyimide. In some embodiments, the interposer 1704 may be formed of alternate rigid or flexible materials that may include the same materials described above for use in a semiconductor substrate, such as silicon, germanium, and other group III-V and group IV materials. The interposer 1704 may include metal interconnects 1708 and vias 1710, including but not limited to TSVs 1706. The interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 13 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 14 is a block diagram of an example electrical device 1800 that may include one or more of the microelectronic assemblies 100 disclosed herein. For example, any suitable ones of the components of the electrical device 1800 may include one or more of the IC device assemblies 1700, IC devices 1600, or dies 1502 disclosed herein, and may be arranged in any of the microelectronic assemblies 100 disclosed herein. A number of components are illustrated in FIG. 14 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 14, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic random access memory (eDRAM) or spin transfer torque magnetic random access memory (STT-MRAM).

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMLS), High Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include an other input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a computing device or a hand-held, portable or mobile computing device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server, or other networked computing component, a printer, a scanner, a monitor, a set-top box, an entertainment control unit, a vehicle control unit, a digital camera, a digital video recorder, or a wearable computing device. In some embodiments, the electrical device 1800 may be any other electronic device that processes data.

### Select Examples

The following paragraphs provide various examples of the embodiments disclosed herein.

Example 1 is a microelectronic assembly, including a first layer including a first die having a first conductive contact; a second die having a second conductive contact; and a pad layer on the first die and the second die, the pad layer including a first pad and a second pad, wherein the first pad is coupled to the first conductive contact and is offset from the first conductive contact in a first direction, and wherein the second pad is coupled to the second conductive contact and is offset from the second conductive contact in a second direction different than the first direction; and a second layer including a third die having a third conductive contact and a fourth conductive contact, where the first layer is coupled to the second layer by an interconnect layer having metal-to-metal bonds and fusion bonds, the first conductive contact is coupled to the third conductive contact by the first pad and one or more of the metal-to-metal bonds, and the second conductive contact is coupled to the fourth conductive contact by the second pad and one or more of the metal-to-metal bonds.

Example 2 may include the subject matter of Example 1, and may further specify that a pitch of adjacent metal-to-metal bonds is between 50 nanometers and 10 microns.

Example 3 may include the subject matter of Example 1, and may further specify that a pitch of adjacent metal-to-metal bonds is between 50 nanometers and 3 microns.

Example 4 may include the subject matter of any of Examples 1-3, and may further include a first via between and coupled to the first conductive contact and the first pad, and a second via between and coupled to the second conductive contact and the second pad.

Example 5 may include the subject matter of any of Examples 1-3, and may further include a first trace between and coupled to the first conductive contact and the first pad, and a second trace between and coupled to the second conductive contact and the second pad.

Example 6A may include the subject matter of any of Examples 1-5, and may further specify that the pad layer is a first pad layer, and the microelectronic assembly may further include a second pad layer between the first pad layer and the interconnect layer, the second pad layer including a third pad and a fourth pad, wherein the third pad is coupled to the first pad and is offset from the first pad in the first direction, and wherein the fourth pad is coupled to the second pad and is offset from the second pad in the second direction.

Example 6B may include the subject matter of any of Examples 1-5, and may further specify that the pad layer is a first pad layer, and the microelectronic assembly may further include a second pad layer between the interconnect layer and the third die, the second pad layer including a third pad and a fourth pad, wherein the third pad is coupled to the third conductive contact and the third conductive contact is offset from the third pad in the first direction, and wherein the fourth pad is coupled to the fourth conductive contact and the fourth conductive contact is offset from the fourth pad in the second direction.

Example 7 may include the subject matter of any of Examples 1-6, and may further specify that the first layer further includes an insulating material surrounding the first die and the second die, and the pad layer is on the insulating material.

Example 8 may include the subject matter of Example 7, and may further specify that the first layer further includes a via through the insulating material, and the pad layer further includes a third pad coupled to the via.

Example 9 is a microelectronic assembly, including a first layer including a first die having a first conductive contact; a second die having a second conductive contact; and a pad layer on the first die and the second die, the pad layer including a first pad and a second pad, wherein the first pad is coupled to the first conductive contact and is offset from the first conductive contact in a first direction by a first dimension, and wherein the second pad is coupled to the second conductive contact and is offset from the second conductive contact in the first direction by a second dimension different than the first dimension; and a second layer including a third die having a third conductive contact and a fourth conductive contact, wherein the first layer is coupled to the second layer an interconnect layer having metal-to-metal bonds and fusion bonds; the first conductive contact is coupled to the third conductive contact by the first pad and one or more of the interconnects; and the second conductive contact is coupled to the fourth conductive contact by the second pad and one or more of the interconnects.

Example 10 may include the subject matter of Example 9, and may further specify that a pitch of adjacent metal-to-metal bonds is between 50 nanometers and 10 microns.

Example 11 may include the subject matter of Examples 9 or 10, and may further specify that the pad layer is a first pad layer, and the microelectronic assembly may further include a second pad layer between the first pad layer and the interconnect layer, the second pad layer including a third pad and a fourth pad, wherein the third pad is coupled to the first pad and is offset from the first pad in the first direction by the first dimension, and wherein the fourth pad is coupled to the second pad and is offset from the second pad in the first direction by the second dimension.

Example 12 may include the subject matter of Examples 9 or 10, and may further specify that the pad layer is a first pad layer, and the microelectronic assembly may further include a second pad layer between the interconnect layer and the third die, the second pad layer including a third pad and a fourth pad, wherein the third pad is coupled to the third conductive contact and the third conductive contact is offset from the third pad in the first direction by the first dimension, and wherein the fourth pad is coupled to the fourth conductive contact and the fourth conductive contact is offset from the fourth pad in the first direction by the second dimension.

Example 13 may include the subject matter of any of Examples 9-12, and may further specify that the first direction is a first rotational direction.

Example 14 may include the subject matter of any of Examples 9-12, and may further specify that the first pad is further offset from the first conductive contact in a second direction different than the first direction.

Example 15 may include the subject matter of Example 14, and may further specify that the first pad is offset from the first conductive contact in the second direction by a third dimension different than the first dimension and the second dimension.

Example 16A may include the subject matter of any of Examples 9-15, and may further include a first via between and coupled to the first conductive contact and the first pad, and a second via between and coupled to the second conductive contact and the second pad.

Example 16B may include the subject matter of any of Examples 9-15, and may further include a first trace between and coupled to the first conductive contact and the first pad, and a second trace between and coupled to the second conductive contact and the second pad.

Example 16C may include the subject matter of any of Examples 9-15, and may further include an insulating material surrounding the first die, the second die, and the third die.

Example 17 is a microelectronic assembly, including a first layer including a first die having a first conductive contact; a second die having a second conductive contact; and a pad layer on the first die and the second die, the pad layer including a first pad and a second pad, wherein the first pad is coupled to the first conductive contact and is offset from the first conductive contact in a first direction by a first dimension, and wherein the second pad is coupled to the second conductive contact and is offset from the second conductive contact in a second direction by a second dimension, wherein the second direction is different than the first direction and the second dimension is different than the first dimension; and a second layer including a third die having a third conductive contact and a fourth conductive contact, where the first layer is coupled to the second layer by an interconnect layer having metal-to-metal bonds and fusion bonds; the first conductive contact is coupled to the third conductive contact by the first pad and one or more of the metal-to-metal bonds; and the second conductive contact is coupled to the fourth conductive contact by the second pad and one or more of the metal-to-metal bonds.

Example 18 may include the subject matter of Example 17, and may further specify that a pitch of adjacent metal-to-metal bonds is between 50 nanometers and 10 microns.

Example 19A may include the subject matter of Examples 17 or 18, and may further include a first via between and coupled to the first conductive contact and the first pad, and a second via between and coupled to the second conductive contact and the second pad.

Example 19B may include the subject matter of Examples 17 or 18, and may further include a first trace between and coupled to the first conductive contact and the first pad, and a second trace between and coupled to the second conductive contact and the second pad.

Example 20 may include the subject matter of any of Examples 17-19, and may further specify that the pad layer is a first pad layer, and the microelectronic assembly may further include a second pad layer between the first pad layer and the interconnect layer, the second pad layer including a third pad and a fourth pad, wherein the third pad is coupled to the first pad and is offset from the first pad in the first direction by the first dimension, and wherein the fourth pad is coupled to the second pad and is offset from the second pad in the second direction by the second dimension.

Example 21 may include the subject matter of any of Examples 17-19, and may further specify that the pad layer is a first pad layer, and the microelectronic assembly may further include a second pad layer between the interconnect layer and the third die, the second pad layer including a third pad and a fourth pad, wherein the third pad is coupled to the third conductive contact and the third conductive contact is offset from the third pad in the first direction by the first dimension, and wherein the fourth pad is coupled to the fourth conductive contact and the fourth conductive contact is offset from the fourth pad in the first direction by the second dimension.

Example 22 may include the subject matter of any of Examples 17-21, and may further specify that the first die, the second die, and the third die include active surfaces, and the active surfaces of the first die and the second die face away from the active surface of the third die.

Example 23 may include the subject matter of any of Examples 17-21, and may further specify that the first die, the second die, and the third die include active surfaces, and the active surfaces of the first die and the second die face towards the active surface of the third die.

Example 24 may include the subject matter of any of Examples 17-21, and may further specify that the first die, the second die, and the third die include back surfaces opposite active surfaces, and the back surfaces of the first die and the second die face towards the back surface of the third die.

Example 25 is a microelectronic assembly, including a first layer including a first die having a first conductive contact; a second die having a second conductive contact; and a first pad layer on the first die and the second die, the first pad layer including a first pad and a second pad, wherein the first pad is coupled to the first conductive contact and is offset from the first conductive contact in a first direction by a first dimension, and wherein the second pad is coupled to the second conductive contact and is offset from the second conductive contact in a second direction by a second dimension, wherein the second direction is different than the first direction and the second dimension is different than the first dimension; a second layer including a third die having a first surface with a third conductive contact and a fourth conductive contact, and an opposing second surface with a fifth conductive contact; and a second pad layer on the second surface of the third die, the second pad layer including a third pad, wherein the third pad is coupled to the fifth conductive contact and is offset from the fifth conductive contact in a third direction by a third dimension; and a third layer including a fourth die having a sixth conductive contact, and may further specify that the first layer is coupled to the second layer by a first interconnect layer having first metal-to-metal bonds and first fusion bonds; that the first conductive contact is coupled to the third conductive contact by the first pad and one or more of the first metal-to-metal bonds; that the second conductive contact is coupled to the fourth conductive contact by the second pad and one or more of the first metal-to-metal bonds; that the second layer is coupled to the third layer by a second interconnect layer having second metal-to-metal bonds and second fusion bonds; and that the fifth conductive contact is coupled to the sixth conductive contact by the third pad and one or more of the second metal-to-metal bonds.

Example 26 may include the subject matter of Example 25, and may further specify that a pitch of adjacent first metal-to-metal bonds and second metal-to-metal bonds is between 50 nanometers and 10 microns.

Example 27 may include the subject matter of Examples 25 or 26, and may further include a first via between and coupled to the first conductive contact and the first pad, and a second via between and coupled to the second conductive contact and the second pad.

Example 28 may include the subject matter of Examples 25 or 26, and may further include a first trace between and coupled to the first conductive contact and the first pad, and a second trace between and coupled to the second conductive contact and the second pad.

Example 29 may include the subject matter of Examples 25 or 26, and may further include a third via between and coupled to the fifth conductive contact and the third pad.

Example 30 may include the subject matter of Examples 25 or 26, and may further include a third trace between and coupled to the fifth conductive contact and the third pad.

1. A microelectronic assembly, comprising:
a first layer including:
a first die having a first conductive contact;
a second die having a second conductive contact; and
a pad layer on the first die and the second die, the pad layer including a first pad and a second pad, wherein the first pad is coupled to the first conductive contact and is offset from the first conductive contact in a first direction, and wherein the second pad is coupled to the second conductive contact and is offset from the second conductive contact in a second direction different than the first direction; and
a second layer including a third die having a third conductive contact and a fourth conductive contact, wherein:
the first layer is coupled to the second layer by an interconnect layer having metal-to-metal bonds and fusion bonds,
the first conductive contact is coupled to the third conductive contact by the first pad and one or more of the metal-to-metal bonds, and
the second conductive contact is coupled to the fourth conductive contact by the second pad and one or more of the metal-to-metal bonds.

2. The microelectronic assembly of claim 1, wherein a pitch of adjacent metal-to-metal bonds is between 50 nanometers and 10 microns.

3. The microelectronic assembly of claim 1, further comprising:
a first via between and coupled to the first conductive contact and the first pad; and
a second via between and coupled to the second conductive contact and the second pad.

4. The microelectronic assembly of claim 1, further comprising:
a first trace between and coupled to the first conductive contact and the first pad; and
a second trace between and coupled to the second conductive contact and the second pad.

5. The microelectronic assembly of claim 1, wherein the pad layer is a first pad layer, and the microelectronic assembly, further comprising:
a second pad layer between the first pad layer and the interconnect layer, the second pad layer including a third pad and a fourth pad, wherein the third pad is coupled to the first pad and is offset from the first pad in the first direction, and wherein the fourth pad is coupled to the second pad and is offset from the second pad in the second direction.

6. The microelectronic assembly of claim 1, wherein the pad layer is a first pad layer, and the microelectronic assembly, further comprising:
a second pad layer between the interconnect layer and the third die, the second pad layer including a third pad and a fourth pad, wherein the third pad is coupled to the third conductive contact and the third conductive contact is offset from the third pad in the first direction, and wherein the fourth pad is coupled to the fourth conductive contact and the fourth conductive contact is offset from the fourth pad in the second direction.

7. The microelectronic assembly of claim 1, wherein the first layer further includes an insulating material surrounding the first die and the second die, and the pad layer is on the insulating material.

8. The microelectronic assembly of claim 7, wherein the first layer further includes a via through the insulating material, and the pad layer further includes a third pad coupled to the via.

9. A microelectronic assembly, comprising:
a first layer including:
a first die having a first conductive contact;
a second die having a second conductive contact; and
a pad layer on the first die and the second die, the pad layer including a first pad and a second pad, wherein the first pad is coupled to the first conductive contact and is offset from the first conductive contact in a first direction by a first dimension, and wherein the second pad is coupled to the second conductive contact and is offset from the second conductive contact in the first direction by a second dimension different than the first dimension; and
a second layer including a third die having a third conductive contact and a fourth conductive contact, wherein:
the first layer is coupled to the second layer an interconnect layer having metal-to-metal bonds and fusion bonds,
the first conductive contact is coupled to the third conductive contact by the first pad and one or more of the metal-to-metal bonds, and
the second conductive contact is coupled to the fourth conductive contact by the second pad and one or more of the metal-to-metal bonds.

10. The microelectronic assembly of claim 9, wherein a pitch of adjacent metal-to-metal bonds is between 50 nanometers and 10 microns.

11. The microelectronic assembly of claim 9, wherein the pad layer is a first pad layer, and the microelectronic assembly, further comprising:
a second pad layer between the first pad layer and the interconnect layer, the second pad layer including a third pad and a fourth pad, wherein the third pad is coupled to the first pad and is offset from the first pad in the first direction by the first dimension, and wherein the fourth pad is coupled to the second pad and is offset from the second pad in the first direction by the second dimension.

12. The microelectronic assembly of claim 9, wherein the pad layer is a first pad layer, and the microelectronic assembly, further comprising:
a second pad layer between the interconnect layer and the third die, the second pad layer including a third pad and a fourth pad, wherein the third pad is coupled to the third conductive contact and the third conductive contact is offset from the third pad in the first direction by the first dimension, and wherein the fourth pad is coupled to the fourth conductive contact and the fourth conductive contact is offset from the fourth pad in the first direction by the second dimension.

13. The microelectronic assembly of claim 9, wherein the first direction is a first rotational direction.

14. The microelectronic assembly of claim 9, wherein the first pad is further offset from the first conductive contact in a second direction different than the first direction.

15. The microelectronic assembly of claim 14, wherein the first pad is offset from the first conductive contact in the second direction by a third dimension different than the first dimension and the second dimension.

16. The microelectronic assembly of claim 9, further comprising:
an insulating material surrounding the first die, the second die, and the third die.

17. A microelectronic assembly, comprising:
a first layer including:
a first die having a first conductive contact;
a second die having a second conductive contact; and
a pad layer on the first die and the second die, the pad layer including a first pad and a second pad, wherein the first pad is coupled to the first conductive contact and is offset from the first conductive contact in a first direction by a first dimension, and wherein the second pad is coupled to the second conductive contact and is offset from the second conductive contact in a second direction by a second dimension, wherein the second direction is different than the first direction and the second dimension is different than the first dimension; and
a second layer including a third die having a third conductive contact and a fourth conductive contact, wherein:
the first layer is coupled to the second layer by an interconnect layer having metal-to-metal bonds and fusion bonds;
the first conductive contact is coupled to the third conductive contact by the first pad and one or more of the metal-to-metal bonds; and
the second conductive contact is coupled to the fourth conductive contact by the second pad and one or more of the metal-to-metal bonds.

18. The microelectronic assembly of claim 17, wherein a pitch of adjacent metal-to-metal bonds is between 50 nanometers and 10 microns.

19. The microelectronic assembly of claim 17, further comprising:
a first via between and coupled to the first conductive contact and the first pad; and
a second via between and coupled to the second conductive contact and the second pad.

20. The microelectronic assembly of claim 17, wherein the pad layer is a first pad layer, and the microelectronic assembly, further comprising:
a second pad layer between the first pad layer and the interconnect layer, the second pad layer including a third pad and a fourth pad, wherein the third pad is coupled to the first pad and is offset from the first pad in the first direction by the first dimension, and wherein the fourth pad is coupled to the second pad and is offset from the second pad in the second direction by the second dimension.
